(19) United States
(12) Patent Application Publication
(10) Pub. No.: US 2026/0239735 A1
(43) Pub. Date: Aug. 13, 2026

(54) SEMICONDUCTOR DEVICE AND METHOD OF FABRICATING THE SAME

(71) Applicant: Samsung Electronics Co., Ltd., Suwon-si (KR)

(72) Inventors: PANJAE PARK, Suwon-si (KR); Seung CHOI, Suwon-si (KR); BYUNG-SUNG KIM, Suwon-si (KR); KWANYOUNG CHUN, Suwon-si (KR)

(21) Appl. No.: 19/300,238

(22) Filed: Aug. 14, 2025

(30) Foreign Application Priority Data
Feb. 7, 2025 (KR) 10-2025-0016004

(51) Int. Cl. H10D 84/90; H10D 89/10

(52) U.S. Cl. CPC H10D 84/922; H10D 84/953; H10D 84/981; H10D 89/10

(57) ABSTRACT

A semiconductor device includes first and second power lines disposed on a substrate and spaced apart from each other in a first direction parallel to a top surface of the substrate, a first standard cell defined between the first and second power lines, and a first wide cell adjacent to the first standard cell. A cell height of the first wide cell may be 1.25 to 1.75 times a pitch between the first and second power lines. The first standard cell and the first wide cell may include first active patterns, respectively, which are connected to each other. A top surface of the first active pattern of the first wide cell may be wider than that of the first active pattern of the first standard cell, when measured in the first direction.

### CROSS-REFERENCE TO RELATED APPLICATIONS

This U.S. non-provisional patent application claims priority under 35 U.S.C. § 119 to Korean Patent Application No. 10-2025-0016004, filed on Feb. 7, 2025, in the Korean Intellectual Property Office, the entire contents of which are hereby incorporated by reference.

### BACKGROUND

The present disclosure relates to a semiconductor device and a method of fabricating the same, and in particular, to a semiconductor device including a field effect transistor and a method of fabricating the same.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize the semiconductor devices with high performance.

### SUMMARY

An embodiment of the inventive concept provides a semiconductor device with an increased integration density and a method of fabricating the same.

An embodiment of the inventive concept provides a semiconductor device with improved electrical characteristics and with improved design flexibility and a method of fabricating the same.

According to an embodiment of the inventive concept, a semiconductor device may include a first power line and a second power line disposed on a substrate and spaced apart from each other in a first direction parallel to a top surface of the substrate, a first standard cell defined between the first power line and the second power line, and a first wide cell adjacent to the first standard cell. A cell height of the first wide cell may be 1.25 to 1.75 times a pitch between the first power line and the second power line. Each of the first standard cell and the first wide cell may include a first active pattern. The first active pattern of the first standard cell may be connected to the first active pattern of the first wide cell. A width of a top surface of the first active pattern of the first wide cell may be larger than a width of a top surface of the first active pattern of the first standard cell, when measured in the first direction.

According to an embodiment of the inventive concept, a semiconductor device may include a first power line and a second power line disposed on a substrate and spaced apart from each other in a first direction parallel to a top surface of the substrate, a first standard cell defined between the first power line and the second power line, a second standard cell adjacent to the first standard cell in the first direction, a first wide cell adjacent to the first standard cell, a first active pattern extended from the first standard cell to the first wide cell, a second active pattern extended in the first standard cell, a third active pattern extended from the second standard cell to the first wide cell, and a fourth active pattern extended in the second standard cell. The first wide cell may be spaced apart from the fourth active pattern in the first direction. A width of a top surface of the first active pattern in the first wide cell may be larger than a width of a top surface of the first active pattern in the first standard cell, when measured in the first direction, and a width of a top surface of the third active pattern in the first wide cell may be larger than a width of a top surface of the third active pattern in the second standard cell.

According to an embodiment of the inventive concept, a semiconductor device may include a first power line and a second power line disposed on a substrate and spaced apart from each other in a first direction parallel to a top surface of the substrate, a first standard cell defined between the first power line and the second power line, a second standard cell adjacent to the first standard cell in the first direction, a third standard cell spaced apart from the first standard cell in the first direction, with the second standard cell interposed therebetween, a first wide cell adjacent to the first standard cell in a second direction crossing the first direction, and a second wide cell adjacent to the third standard cell in the second direction and adjacent to the first wide cell in the first direction. A cell height of each of the first and second wide cells may be 1.25 to 1.75 times a pitch between the first and second power lines.

According to an embodiment of the inventive concept, a method of fabricating a semiconductor device may include forming a first standard cell and a second standard cell adjacent to each other in a first direction parallel to a top surface of a substrate and forming a first wide cell adjacent to the first standard cell in a second direction crossing the first direction. The forming of the first and second standard cells and the first wide cell may include forming a first active pattern extending from the first standard cell to the first wide cell; forming a second active pattern extended in the first standard cell; forming a third active pattern extending from the second standard cell to the first wide cell; forming a fourth active pattern extended in the second standard cell. Here, the first wide cell may be spaced apart from the fourth active pattern in the first direction. When measured in the first direction, a width of a top surface of the first active pattern in the first wide cell may be larger than a width of a top surface of the first active pattern in the first standard cell, and a width of a top surface of the third active pattern in the first wide cell may be larger than a width of a top surface of the third active pattern in the second standard cell.

In an embodiment, the method may further include forming a first power line and a second power line, which are extended in the second direction and are spaced apart from each other in the first direction, on the substrate. The first standard cell may be defined between the first power line and the second power line.

In an embodiment, the method may further include forming a first source/drain pattern which contains n-type impurities, on the first active pattern; and forming a second source/drain pattern, which contains p-type impurities, on each of the second and third active patterns.

In an embodiment, the method may further include forming a first cutting pattern between the first standard cell and the second standard cell and forming a second cutting pattern between the third active pattern of the first wide cell and the fourth active pattern.

In an embodiment, a width of the fourth active pattern in the first direction may increase as it goes further in the second direction.

In an embodiment, when measured along the second direction, the fourth active pattern may have a constant width in the first direction.

In an embodiment, a cell height of the first wide cell may be 1.25 to 1.75 times a cell height of the first standard cell.

### BRIEF DESCRIPTION OF THE DRAWINGS

FIGS. 1 to 4 are conceptual diagrams illustrating logic cells of a semiconductor device according to an example embodiment of the inventive concept.

FIG. 5 is a block diagram illustrating a group cell of a semiconductor device according to an example embodiment of the inventive concept.

FIG. 6 is a plan view illustrating a group cell of a semiconductor device according to an example embodiment of the inventive concept.

FIG. 7 is a plan view illustrating a first wide cell of a group cell of a semiconductor device according to an example embodiment of the inventive concept.

FIG. 8 is a plan view illustrating a second wide cell of a group cell of a semiconductor device according to an example embodiment of the inventive concept.

FIG. 9 is a sectional view corresponding to a line A-A′ of FIG. 6.

FIG. 10 is a sectional view corresponding to a line B-B′ of FIG. 6.

FIG. 11 is a sectional view corresponding to a line C-C′ of FIG. 6.

FIG. 12 is a sectional view corresponding to a line D-D′ of FIG. 6.

FIG. 13 is a sectional view corresponding to a line E-E′ of FIG. 6.

FIG. 14 is a block diagram illustrating a group cell of a semiconductor device according to an example embodiment of the inventive concept.

FIG. 15 is a plan view illustrating a group cell of a semiconductor device according to an example embodiment of the inventive concept.

FIG. 16 is a block diagram illustrating a group cell of a semiconductor device according to an example embodiment of the inventive concept.

FIG. 17 is a plan view illustrating a group cell of a semiconductor device according to an example embodiment of the inventive concept.

FIGS. 18 to 20 are block diagrams illustrating a group cell of a semiconductor device according to example embodiments of the inventive concept.

FIGS. 21 and 22 are plan views illustrating a group cell of a semiconductor device according to example embodiments of the inventive concept.

FIGS. 23 to 31 are diagrams illustrating a method of fabricating a semiconductor device, according to an example embodiment of the inventive concept.

### DETAILED DESCRIPTION

Example embodiments of the inventive concepts will now be described more fully with reference to the accompanying drawings, in which example embodiments are shown. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

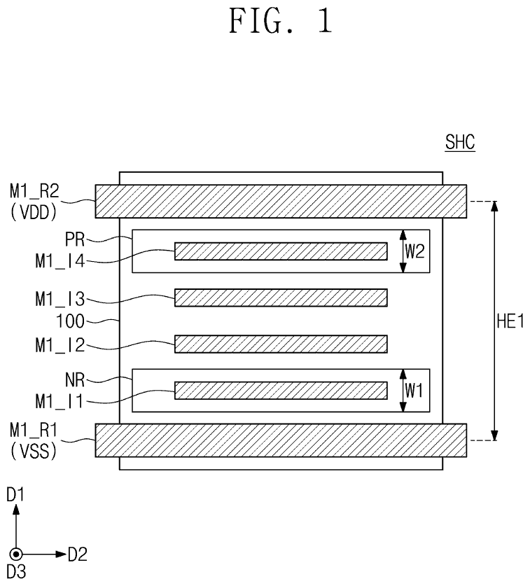

FIGS. 1 to 4 are conceptual diagrams illustrating logic cells of a semiconductor device according to an example embodiment of the inventive concept.

Referring to FIG. 1, a standard cell SHC may be provided. In detail, a first power line M1_R1 and a second power line M1_R2 may be provided on a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The standard cell SHC may be defined between the first power line M1_R1 and the second power line M1_R2. The standard cell SHC may include one first region NR and one second region PR. In an embodiment, the first region NR may be an NMOSFET region, and the second region PR may be a PMOSFET region. For example, the standard cell SHC may have a CMOS structure provided between the first power line M1_R1 and the second power line M1_R2.

As an example, the first and second regions NR and PR of the standard cell SHC are illustrated to be sequentially arranged in a first direction D1, but the inventive concept is not limited to this example. As another example, the second region PR and the first region NR of the standard cell SHC may be sequentially arranged in the first direction D1.

When measured in the first direction D1 parallel to a top surface of the substrate 100, the first region NR may have a first width W1, and the second region PR may have a second width W2. In the present specification, a width of the first region NR may be defined as a width of a top surface of an active pattern, which is provided on the first region NR and will be described below. In addition, a width of the second region PR may be defined as a width of a top surface of an active pattern, which is provided on the second region PR and will be described below.

A length in the first direction D1 of the standard cell SHC (i.e., the cell height of the standard cell SHC) may be defined as a first height HE1. The first height HE1 may be substantially equal to a distance (e.g., a pitch) between the first power line M1_R1 and the second power line M1_R2.

First to fourth lower interconnection lines M1_I1, M1_I2, M1_I3, and M1_I4 may be provided between the first power line M1_R1 and the second power line M1_R2. The first to fourth lower interconnection lines M1_I1, M1_I2, M1_I3, and M1_I4 may be extended lengthwise in a second direction D2 to be parallel to each other. The first power line M1_R1, the second power line M1_R2, and the first to fourth lower interconnection lines M1_I1, M1_I2, M1_I3, and M1_I4 may constitute a first metal layer M1, which will be described below.

The standard cell SHC may constitute a single logic cell. In the present specification, the logic cell may mean a logic device (e.g., AND, OR, XOR, XNOR, MUX, inverter, and so forth), which is configured to execute a specific function. In other words, the logic cell may include transistors constituting the logic device and interconnection lines connecting the transistors to each other.

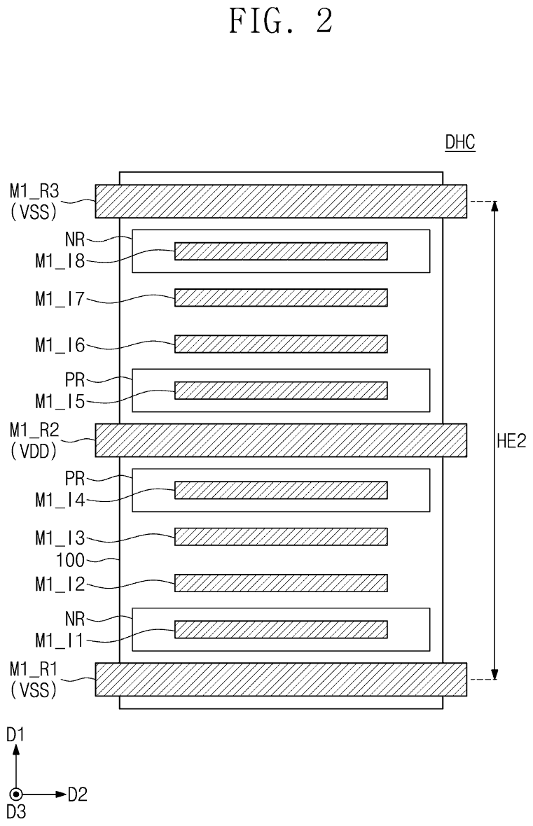

Referring to FIG. 2, a double height cell DHC may be provided. In an embodiment, a cell height HE2 of the double height cell DHC may be about two times the first height HE1 of the standard cell SHC. In an embodiment, the double height cell DHC may be composed of two standard cells SHC that are adjacent to each other in the first direction D1.

The first power line M1_R1, the second power line M1_R2, and a third power line M1_R3, which are spaced apart from each other in the first direction D1, may be sequentially provided on the substrate 100. The third power line M1_R3 may be a conduction path, to which the source voltage VSS is provided.

The double height cell DHC may be defined between the first power line M1_R1 and the third power line M1_R3. The double height cell DHC may include a pair of first regions NR and a pair of second regions PR. One of the first regions NR paired may be adjacent to the first power line M1_R1, and the other may be adjacent to the third power line M1_R3. The pair of second regions PR may be interposed between the pair of first regions NR and may be adjacent to the second power line M1_R2.

Fifth to eighth lower interconnection lines M1_I5, M1_I6, M1_I7, and M1_I8 may be interposed between the second power line M1_R2 and the third power line M1_R3. The fifth to eighth lower interconnection lines M1_I5, M1_I6, M1_I7, and M1_I8 may be extended lengthwise to be parallel to each other. The fifth to eighth lower interconnection lines M1_I5, M1_I6, M1_I7, and M1_I8, along with the afore-described elements, may constitute the first metal layer M1, which will be described below.

The length of the double height cell DHC in the first direction D1 may be defined as a second height HE2. The second height HE2 may be about two times the first height HE1 of FIG. 1. In an embodiment, the pair of second regions PR of the double height cell DHC may be combined to serve as a single PMOSFET region.

In an embodiment, although not shown, a triple height cell whose cell height is three times the standard cell SHC, may be provided.

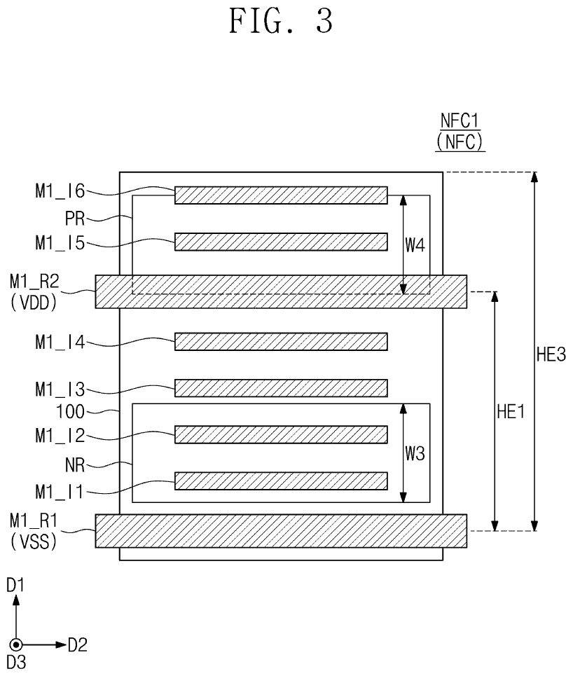

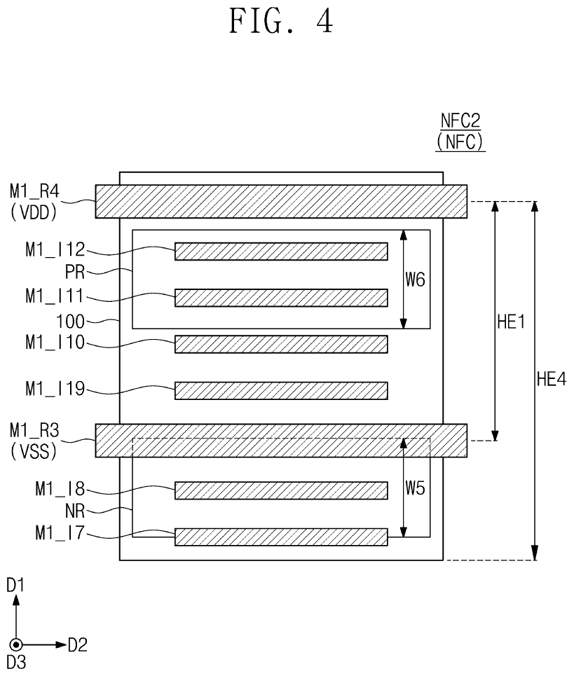

Referring to FIGS. 3 and 4, a wide cell NFC may be provided. The wide cell NFC in the embodiment of FIG. 3 may be a first wide cell NFC1, and the wide cell NFC in the embodiment of FIG. 4 may be a second wide cell NFC2.

The first power line M1_R1 and the second power line M1_R2 may be provided to cross the first wide cell NFC1. The third power line M1_R3 and a fourth power line M1_R4 may be provided to cross the second wide cell NFC2.

The length of the first wide cell NFC1 in the first direction D1 may be defined as a third height HE3. The length of the second wide cell NFC2 in the first direction D1 may be defined as a fourth height HE4. In an embodiment, each of the third height HE3 and the fourth height HE4 may be 1.25 to 1.75 times the pitch between the first power line M1 _R1 and the second power line M1_R2. Each of the third height HE3 and the fourth height HE4 may be greater than the first height HE1. In an embodiment, each of the third height HE3 and the fourth height HE4 may be 1.25 to 1.75 times the first height HE1. Each of the third height HE3 and the fourth height HE4 may be smaller than the second height HE2.

For example, an area of each of the first and second wide cells NFC1 and NFC2 may be smaller than that of the double height cell DHC. As a result, the integration density of the semiconductor device may be increased.

Each of the first and second wide cells NFC1 and NFC2 may include one first region NR and one second region PR. In an embodiment, the first region NR may be an NMOSFET region, and the second region PR may be a PMOSFET region. For example, each of the first and second wide cells NFC1 and NFC2 may have a CMOS structure.

When viewed in a plan view, the first region NR of the first wide cell NFC1 may be interposed between the first power line M1_R1 and the second power line M1_R2. A portion of the second region PR of the first wide cell NFC1 may be vertically overlapped with the second power line M1_R2. Another portion of the second region PR of the first wide cell NFC1 may be shifted from the second power line M1_R2 in the first direction D1. When viewed in a plan view, the second power line M1_R2 may be interposed between the first region NR of the first wide cell NFC1 and another portion of the second region PR of the first wide cell NFC1.

When viewed in a plan view, the second region PR of the second wide cell NFC2 may be interposed between the third power line M1_R3 and the fourth power line M1_R4. A portion of the first region NR of the second wide cell NFC2 may be vertically overlapped with the third power line M1_R3. Another portion of the first region NR of the second wide cell NFC2 may be shifted from the third power line M1_R3 in an opposite direction of the first direction D1. When viewed in a plan view, the third power line M1_R3 may be interposed between another portion of the first region NR of the second wide cell NFC2 and the second region PR of the second wide cell NFC2.

When measured in the first direction D1 parallel to the top surface of the substrate 100, the first region NR of the first wide cell NFC1 may have a third width W3, and the second region PR of the first wide cell NFC1 may have a fourth width W4. When measured in the first direction D1 parallel to the top surface of the substrate 100, the first region NR of the second wide cell NFC2 may have a fifth width W5, and the second region PR of the second wide cell NFC2 may have a sixth width W6.

Each of the third and fifth widths W3 and W5 may be larger than the first width W1. In an embodiment, each of the third and fifth widths W3 and W5 may be 1.1 to 5 times the first width W1. Thus, a channel pattern on the first region NR of each of the first and second wide cells NFC1 and NFC2 may have a larger width than a channel pattern on the first region NR of the standard cell SHC, as will be described later. Each of the fourth and sixth widths W4 and W6 may be larger than the second width W2. In an embodiment, each of the fourth and sixth widths W4 and W6 may be 1.1 to 5 times the second width W2. Thus, a channel pattern on the second region PR of each of the first and second wide cells NFC1 and NFC2 may have a larger width than a channel pattern on the second region PR of the standard cell SHC, as will be described later. As a result, an overlap area between the gate electrode and the channel pattern may be increased, as will be described later, and the electrical characteristics of the semiconductor device may be improved.

The first to sixth lower interconnection lines M1_I1 to M1_I6 may be provided in the first wide cell NFC1. The first to fourth lower interconnection lines M1_I1, M1_I2, M1_I3, and M1_I4 may be provided between the first power line M1_R1 and the second power line M1_R2. The fifth and sixth lower interconnection lines M1_I5 and M1_I6 may be spaced apart from the first to four lower interconnection lines M1_I1, M1_I2, M1_I3, and M1_I4 in the first direction D1, with the second power line M1_R2 interposed therebetween.

Seventh to twelfth lower interconnection lines M1_I7 to M1_I12 may be provided in the second wide cell NFC2. The ninth to twelfth lower interconnection lines M1_I9 to M1_I12 may be interposed between the third power line M1_R3 and the fourth power line M1_R4. The seventh and eighth lower interconnection lines M1_I7 and M1_I8 may be spaced apart from the ninth to twelfth lower interconnection lines M1_I9 to M1_I12 in the first direction D1, with the third power line M1_R3 interposed therebetween. Each of the first and second wide cells NFC1 and NFC2 may have more lines (e.g., lower interconnection lines), which can be used to deliver signals, compared to the standard cell SHC. This may make it possible to increase a degree of freedom in designing the layout of the semiconductor device.

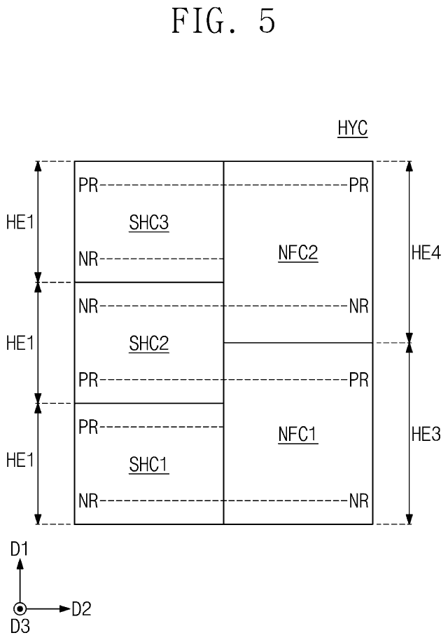

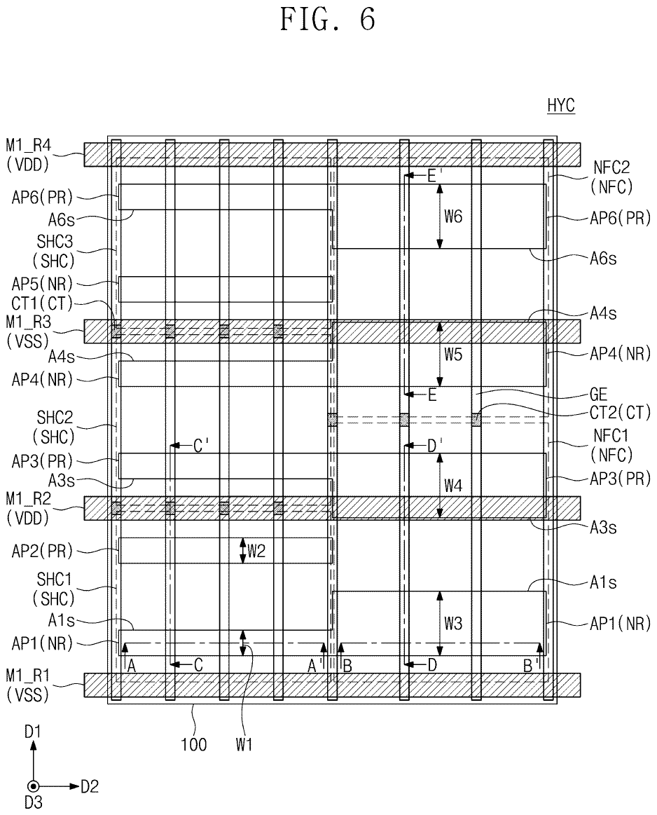

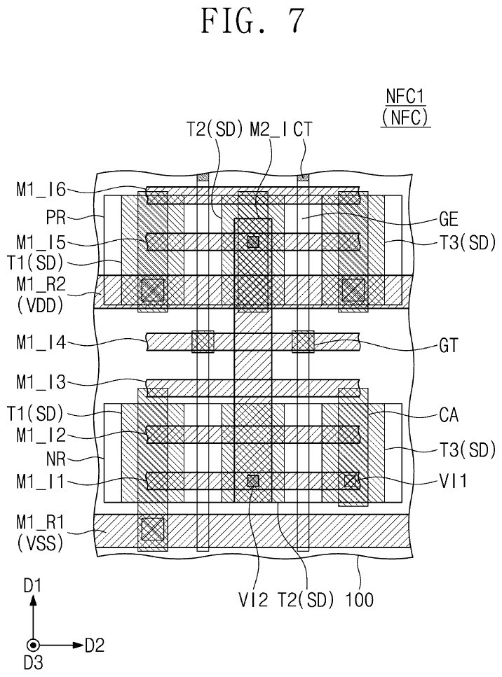

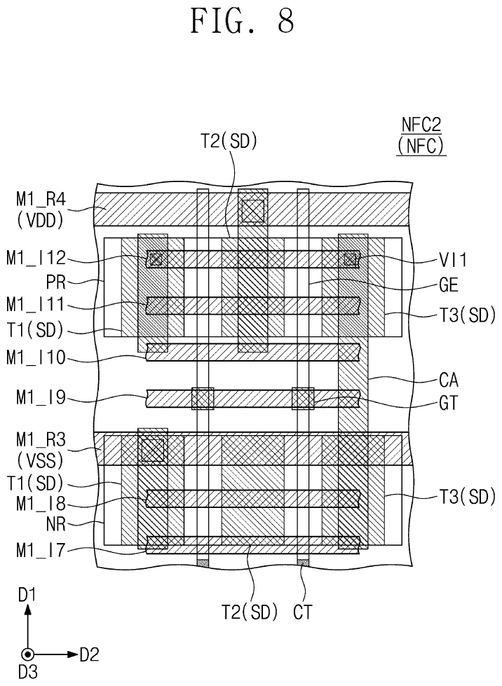

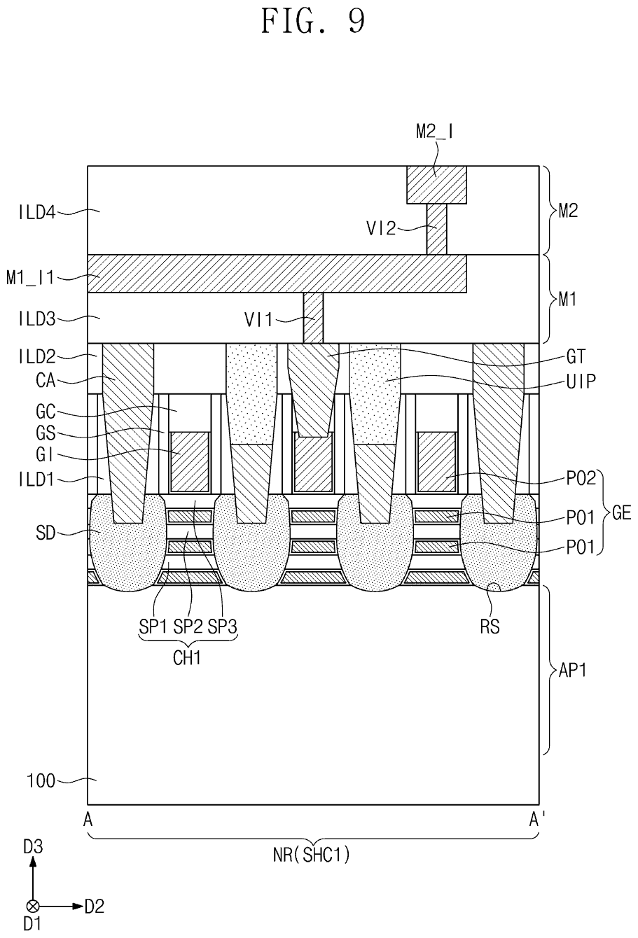

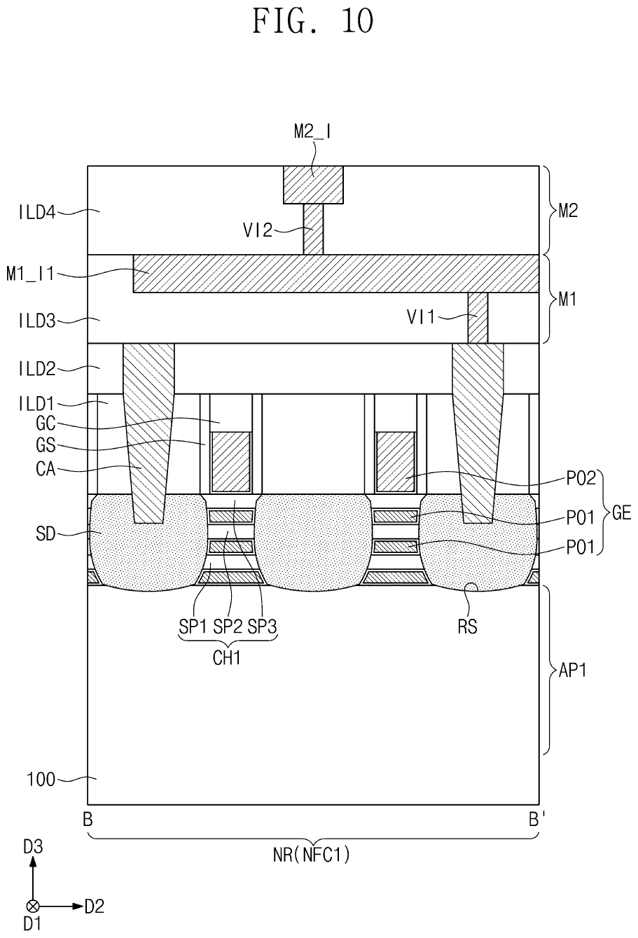

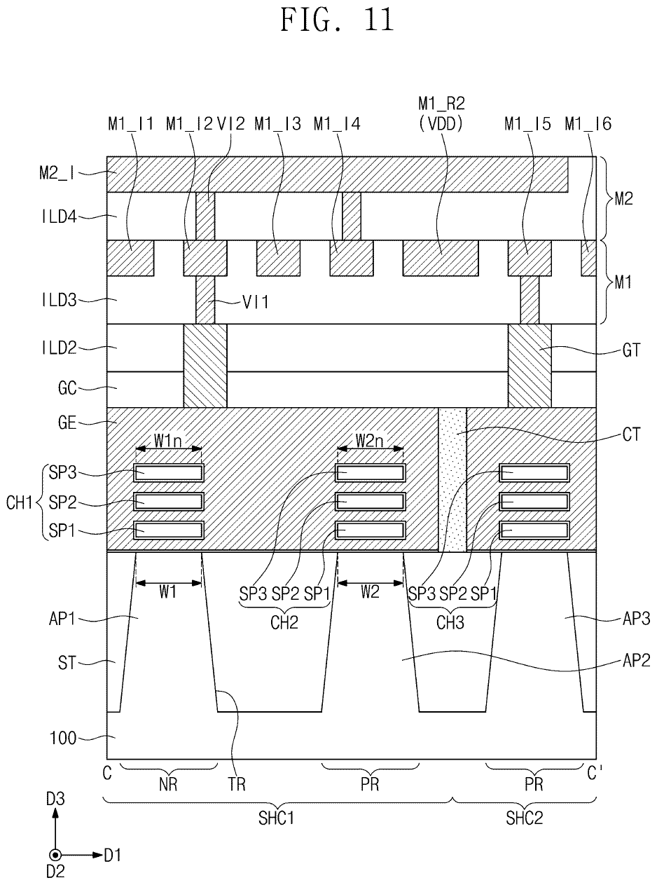

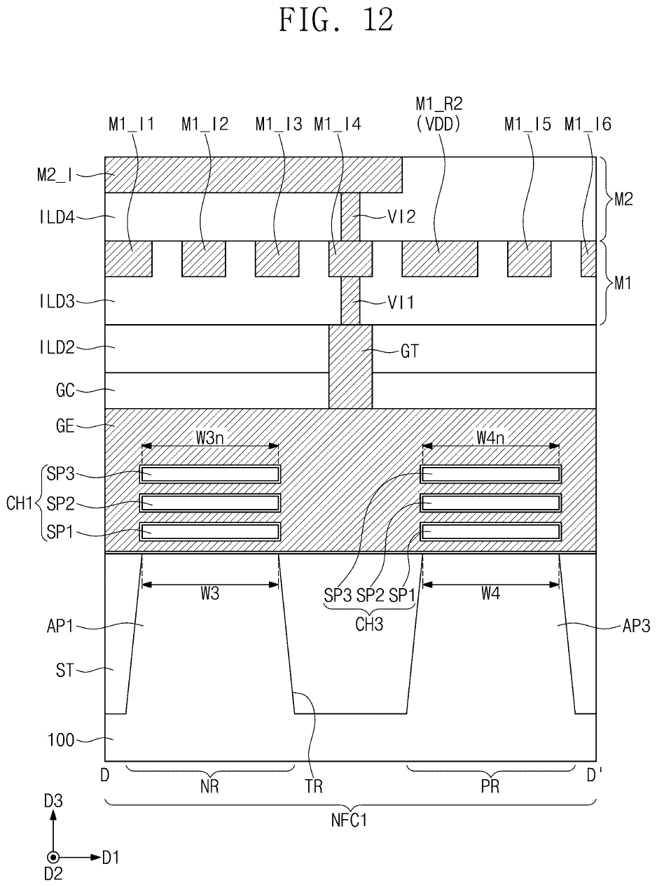

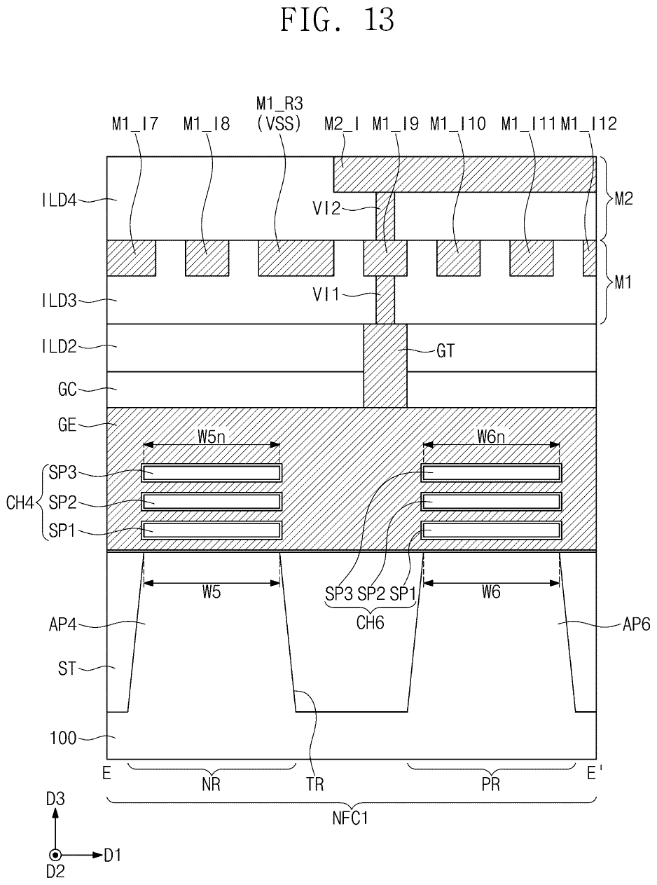

FIG. 5 is a block diagram illustrating a group cell of a semiconductor device according to an example embodiment of the inventive concept. FIG. 6 is a plan view illustrating a group cell of a semiconductor device according to an example embodiment of the inventive concept. FIG. 7 is a plan view illustrating a first wide cell of a group cell of a semiconductor device according to an example embodiment of the inventive concept. FIG. 8 is a plan view illustrating a second wide cell of a group cell of a semiconductor device according to an example embodiment of the inventive concept. FIG. 9 is a sectional view corresponding to a line A-A′ of FIG. 6. FIG. 10 is a sectional view corresponding to a line B-B′ of FIG. 6. FIG. 11 is a sectional view corresponding to a line C-C′ of FIG. 6. FIG. 12 is a sectional view corresponding to a line D-D′ of FIG. 6. FIG. 13 is a sectional view corresponding to a line E-E′ of FIG. 6.

Referring to FIG. 5, a group cell HYC may be provided. The group cell HYC may be group of logic cells having various shapes. The logic cells may be two-dimensionally arranged. For example, in the embodiment of FIG. 5, the group cell HYC may include three standard cells SHC1, SHC2, and SHC3 and two wide cells NFC1 and NFC2.

In detail, the first to third standard cells SHC1, SHC2, and SHC3 may be sequentially disposed in the first direction D1. The first wide cell NFC1 may be adjacent to the first standard cell SHC1 in the second direction D2. The second wide cell NFC2 may be adjacent to the third standard cell SHC3 in the second direction D2. The first and second wide cells NFC1 and NFC2 may be sequentially disposed in the first direction D1.

In an embodiment, the cell height of the group cell HYC may be about three times the first height HE1. As described above, a sum of the cell heights HE1 of the first to third standard cells SHC1, SHC2, and SHC3 may be substantially equal to the cell height of the group cell HYC in the first direction D1. Similarly, a sum of the cell heights HE3 and HE4 of the first and second wide cells NFC1 and NFC2 may be substantially equal to the cell height of the group cell HYC in the first direction D1. Thus, it may be possible to place the first to third standard cells SHC1, SHC2, and SHC3 and the first and second wide cells NFC1 and NFC2 at the ratio of 3:2 within the group cell HYC, without inserting any dummy cell. As a result, for the group cell HYC in the present embodiment, it may be possible to reduce an area loss, compared to the case where the logic cells as well as the dummy cell are placed to constitute the group cell HYC. Thus, the integration density of the semiconductor device may be increased.

In each of the first to third standard cells SHC1, SHC2, and SHC3, the first and second regions NR and PR may be extended in the second direction D2. The first and second regions NR and PR in the first and second standard cells SHC1 and SHC2 may be placed in the same or similar manner as the first and second regions NR and PR in the double height cell DHC described with reference to FIG. 2. In addition, the first region NR of the third standard cell SHC3 may be adjacent to the first region NR of the second standard cell SHC2. The second region PR of the third standard cell SHC3 may be spaced apart from the second region PR of the second standard cell SHC2 in the first direction D1, with the first regions NR of the second and third standard cells SHC2 and SHC3 interposed therebetween.

In each of the first and second wide cells NFC1 and NFC2, the first and second regions NR and PR may be extended in the second direction D2. The first region NR of the first wide cell NFC1, the second region PR of the first wide cell NFC1, the first region NR of the second wide cell NFC2, and the second region PR of the second wide cell NFC2 may be sequentially arranged to be spaced apart from each other in the first direction D1.

The first region NR of the first standard cell SHC1 may be connected to the first region NR of the first wide cell NFC1. In other words, the first region NR may be extended from the first standard cell SHC1 to the first wide cell NFC1. However, in an embodiment, the second region PR of the first standard cell SHC1 may not be extended into the first wide cell NFC1. The second region PR of the first standard cell SHC1 may be spaced apart from the second region PR of the first wide cell NFC1. The second region PR of the first wide cell NFC1 may be shifted from the second region PR of the first standard cell SHC1 in the first direction D1.

The second region PR of the second standard cell SHC2 may be connected to the second region PR of the first wide cell NFC1. In other words, the second region PR may be extended from the second standard cell SHC2 to the first wide cell NFC1. The first region NR of the second standard cell SHC2 may be connected to the first region NR of the second wide cell NFC2. In other words, the first region NR may be extended from the second standard cell SHC2 to the second wide cell NFC2.

However, the first region NR of the third standard cell SHC3 may not be extended into the second wide cell NFC2. The first region NR of the third standard cell SHC3 may be spaced apart from the first region NR of the second wide cell NFC2. The first region NR of the second wide cell NFC2 may be shifted from the first region NR of the third standard cell SHC3 in the opposite direction of the first direction D1. The second region PR of the third standard cell SHC3 may be connected to the second region PR of the second wide cell NFC2. For example, the second region PR may be extended from the third standard cell SHC3 to the second wide cell NFC2.

Hereinafter, the arrangement and structure of the group cell HYC will be described in more detail with reference to FIGS. 6 to 13.

The first to four power lines M1_R1, M1_R2, M1_R3, and M1_R4 may be provided on the substrate 100. In an embodiment, the substrate 100 may be a semiconductor substrate, which is formed of at least one of silicon, germanium, and silicon-germanium, or a compound semiconductor substrate. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements. In an embodiment, the substrate 100 may be an insulating substrate including an insulating material.

The first standard cell SHC1 may be defined between the first power line M1_R1 and the second power line M1_R2. The second standard cell SHC2 may be defined between the second power line M1_R2 and the third power line M1_R3. The third standard cell SHC3 may be defined between the third power line M1_R3 and the fourth power line M1_R4. The second power line M1_R2 may be disposed to cross the first wide cell NFC1. The third power line M1_R3 may be disposed to cross the second wide cell NFC2.

The first region NR of the first wide cell NFC1 may be interposed between the first power line M1_R1 and the second power line M1_R2. A portion of the second region PR of the first wide cell NFC1 and a portion of the first region NR of the second wide cell NFC2 may be interposed between the second power line M1_R2 and the third power line M1_R3. The second region PR of the second wide cell NFC2 may be interposed between the third power line M1_R3 and the fourth power line M1_R4.

First to sixth active patterns AP1 to AP6 may be provided on the substrate 100. each of the first to sixth active patterns AP1 to AP6 may be defined by a trench TR, which is formed in an upper portion of the substrate 100. In an embodiment, the first to sixth active patterns AP1 to AP6 may protrude from the top surface of the substrate 100 in a third direction D3. The third direction D3 may be a direction perpendicular to the top surface of the substrate 100. The first to sixth active patterns AP1 to AP6 may be spaced apart from each other in the first direction D1 and may be extended lengthwise in the second direction D2. In an embodiment, each of the first to sixth active patterns AP1 to AP6 may be formed of or include at least one of silicon (Si), germanium (Ge), or silicon-germanium (SiGe).

The first active pattern AP1 may be extended from the first region NR of the first standard cell SHC1 to the first region NR of the first wide cell NFC1. Each of the first standard cell SHC1 and the first wide cell NFC1 may include the first active pattern AP1. In detail, the first active patterns AP1, which are respectively included in the first standard cell SHC1 and the first wide cell NFC1, may be two different portions of a single active pattern extended lengthwise in the second direction D2.

As defined above, when measured in the first direction D1, a top surface of the first active pattern AP1 of the first standard cell SHC1 may have the first width W1. When measured in the first direction D1, a top surface of the first active pattern AP1 of the first wide cell NFC1 may have the third width W3. The third width W3 may be larger than the first width W1. In an embodiment, the third width W3 may be 1.1 to 5 times the first width W1.

In an embodiment, a side surface A1s of the first active pattern AP1 of the first wide cell NFC1 may protrude in the first direction D1, when compared to a side surface A1s of the first active pattern AP1 of the first standard cell SHC1. For example,, a side surface A1s of the first active pattern AP1 of the first wide cell NFC1 may be offset in the first direction D1 from a side surface A1s of the first active pattern AP1 of the first standard cell SHC1. Alternatively, an opposite side surface of the first active pattern AP1 of the first wide cell NFC1 may be aligned to an opposite side surface of the first active pattern AP1 of the first standard cell SHC1. The side surface A1s of the first active pattern AP1 may be a surface of the first active pattern AP1 exposed to the outside in the first direction D1, and the opposite side surface may be a surface of the first active pattern AP1 exposed to the outside in the opposite direction of the first direction D1.

When viewed in a plan view, the first active pattern AP1 of each of the first standard cell SHC1 and the first wide cell NFC1 may be interposed between the first power line M1_R1 and the second power line M1_R2.

The first standard cell SHC1 may include the second active pattern AP2 on the second region PR. The second active pattern AP2 may be extended in the second direction D2, within the first standard cell SHC1. In an embodiment, the second active pattern AP2 may not be extended into the first wide cell NFC1.

As defined above, when measured in the first direction D1, a top surface of the second active pattern AP2 of the first standard cell SHC1 may have the second width W2. In an embodiment, the third width W3 may be larger than the second width W2. When measured in the second direction D2, a width of the second active pattern AP2 may be substantially equal to a width of the first active pattern AP1 of the first standard cell SHC1. When measured in the second direction D2, the width of the second active pattern AP2 may be smaller than a sum of a width of the first active pattern AP1 of the first standard cell SHC1 and a width of the first active pattern AP1 of the first wide cell NFC1.

A third active pattern AP3 may be extended from the second region PR of the second standard cell SHC2 to the second region PR of the first wide cell NFC1. Each of the second standard cell SHC2 and the first wide cell NFC1 may include the third active pattern AP3. In detail, the third active patterns AP3, which are respectively included in the second standard cell SHC2 and the first wide cell NFC1, may be two different portions of a single active pattern extended in the second direction D2.

As defined above, a top surface of the third active pattern AP3 of the first wide cell NFC1 may have the fourth width W4, when measured in the first direction D1. The fourth width W4 may be larger than a width of a top surface of the third active pattern AP3 of the second standard cell SHC2 in the first direction D1.

In an embodiment, a side surface A3s of the third active pattern AP3 of the first wide cell NFC1 may protrude in the opposite direction of the first direction D1, when compared to a side surface A3s of the third active pattern AP3 of the second standard cell SHC2. Alternatively, an opposite side surface of the third active pattern AP3 of the first wide cell NFC1 may be aligned to an opposite side surface of the third active pattern AP3 of the second standard cell SHC2. The side surface A3s may be a surface of the third active pattern AP3 exposed to the outside in the opposite direction of the first direction D1, and the opposite side surface may be another surface of the third active pattern AP3 exposed to the outside in the first direction D1.

A portion of the third active pattern AP3 of the first wide cell NFC1 may be vertically overlapped with the second power line M1_R2. When viewed in a plan view, the third active pattern AP3 of the second standard cell SHC2 and another portion of the third active pattern AP3 of the first wide cell NFC1 may be interposed between the second power line M1_R2 and the third power line M1_R3.

The third active pattern AP3 of the first wide cell NFC1 may be spaced apart from the second active pattern AP2. The third active pattern AP3 of the first wide cell NFC1 may be shifted from the second active pattern AP2 in the first direction D1.

The fourth active pattern AP4 may be extended from the first region NR of the second standard cell SHC2 to the first region NR of the second wide cell NFC2. Each of the second standard cell SHC2 and the second wide cell NFC2 may include the fourth active pattern AP4. In detail, the fourth active patterns AP4, which are respectively included in the second standard cell SHC2 and the second wide cell NFC2, may be two different portions of a single active pattern extended in the second direction D2.

As defined above, when measured in the first direction D1, a top surface of the fourth active pattern AP4 of the second wide cell NFC2 may have the fifth width W5. The fifth width W5 may be larger than a width of a top surface of the fourth active pattern AP4 of the second standard cell SHC2 in the first direction D1.

In an embodiment, a side surface A4s of the fourth active pattern AP4 of the second wide cell NFC2 may protrude in the first direction D1, when compared to the side surface A4s of the fourth active pattern AP4 of the second standard cell SHC2. Alternatively, an opposite side surface of the fourth active pattern AP4 of the second wide cell NFC2 may be aligned to an opposite side surface of the fourth active pattern AP4 of the second standard cell SHC2. The side surface A4s of the fourth active pattern AP4 may be a surface of the fourth active pattern AP4 exposed to the outside in the first direction D1, and the opposite side surface may be another surface of the fourth active pattern AP4 exposed to the outside in the opposite direction of the first direction D1.

A portion of the fourth active pattern AP4 of the second wide cell NFC2 may be vertically overlapped with the third power line M1_R3. When viewed in a plan view, the fourth active pattern AP4 of the second standard cell SHC2 and another portion of the fourth active pattern AP4 of the second wide cell NFC2 may be interposed between the second power line M1_R2 and the third power line M1_R3.

The third standard cell SHC3 may include the fifth active pattern AP5 on the first region NR. The fifth active pattern AP5 may be extended in the second direction D2, within the third standard cell SHC3. In an embodiment, the fifth active pattern AP5 may not be extended into the second wide cell NFC2.

The sixth active pattern AP6 may be extended from the second region PR of the third standard cell SHC3 to the second region PR of the second wide cell NFC2. Each of the third standard cell SHC3 and the second wide cell NFC2 may include the sixth active pattern AP6. In detail, the sixth active patterns AP6, which are respectively included in the third standard cell SHC3 and the second wide cell NFC2, may be two different portions of a single active pattern extended in the second direction D2.

As defined above, when measured in the first direction D1, a top surface of the sixth active pattern AP6 of the second wide cell NFC2 may have the sixth width W6. The sixth width W6 may be larger than a width of a top surface of the sixth active pattern AP6 of the third standard cell SHC3 in the first direction D1.

In an embodiment, a side surface A6s of the sixth active pattern AP6 of the second wide cell NFC2 may protrude in the opposite direction of the first direction D1, when compared to a side surface A6s of the sixth active pattern AP6 of the third standard cell SHC3. Alternatively, an opposite side surface of the sixth active pattern AP6 of the second wide cell NFC2 may be aligned to an opposite side surface of the sixth active pattern AP6 of the third standard cell SHC3. The side surface A6s may be a surface of the sixth active pattern AP6 exposed to the outside in the opposite direction of the first direction D1, and the opposite side surface may be another surface of the sixth active pattern AP6 exposed to the outside in the first direction D1.

The sixth active pattern AP6 of the second wide cell NFC2 may be spaced apart from the fifth active pattern AP5. The sixth active pattern AP6 of the second wide cell NFC2 may be shifted from the fifth active pattern AP5 in the first direction D1.

When viewed in a plan view, the sixth active pattern AP6 of each of the third standard cell SHC3 and the second wide cell NFC2 may be interposed between the third power line M1_R3 and the fourth power line M1_R4.

A device isolation pattern ST, which is formed of or includes an insulating material, may be provided on the substrate 100 to fill the trench TR. The device isolation pattern ST may be provided to enclose the first to sixth active patterns AP1 to AP6.

First to sixth channel patterns CH1 to CH6 may be provided on the substrate 100. Each of the first to sixth channel patterns CH1 to CH6 may include a first semiconductor pattern SP1, a second semiconductor pattern SP2, and a third semiconductor pattern SP3, which are spaced apart from each other in the third direction D3, but the inventive concept is not limited to this example. In an embodiment, each of the first to third semiconductor patterns SP1, SP2, and SP3 may be formed of or include crystalline silicon.

Each of the first to sixth channel patterns CH1 to CH6 may be provided on a corresponding one of the first to sixth active patterns AP1 to AP6. The first channel pattern CH1 may include a plurality of first channel patterns CH1, which are provided on the first active pattern AP1 and are spaced apart from each other in the second direction D2. The second channel pattern CH2 may include a plurality of second channel patterns CH2, which are provided on the second active pattern AP2 and are spaced apart from each other in the second direction D2. The third channel pattern CH3 may include a plurality of third channel patterns CH3, which are provided on the third active pattern AP3 and are spaced apart from each other in the second direction D2. The fourth channel pattern CH4 may include a plurality of fourth channel patterns CH4, which are provided on the fourth active pattern AP4 and are spaced apart from each other in the second direction D2. A fifth channel pattern (not shown) may include a plurality of fifth channel patterns, which are provided on the fifth active pattern AP5 and are spaced apart from each other in the second direction D2. The sixth channel pattern CH6 may include a plurality of sixth channel patterns CH6, which are provided on the sixth active pattern AP6 and are spaced apart from each other in the second direction D2.

Due to the difference between the first and third widths W1 and W3, a width W3n of the first channel pattern CH1 in the first wide cell NFC1 may be greater than a width W1n of the first channel pattern CH1 in the first standard cell SHC1, when measured in the first direction D1. In the present specification, a width of the channel pattern may be defined as a width of a top surface of the uppermost one of the semiconductor patterns of the channel pattern.

Due to the difference between the width of the top surface of the third active pattern AP3 of the second standard cell SHC2 and the fourth width W4, a width W4n of the third channel pattern CH3 in the first wide cell NFC1 may be larger than a width of the third channel pattern CH3 in the second standard cell SHC2, when measured in the first direction D1.

Due to the difference between the width of the top surface of the fourth active pattern AP4 of the second standard cell SHC2 and the fifth width W5, a width W5n of the fourth channel pattern CH4 in the second wide cell NFC2 may be larger than a width of the fourth channel pattern CH4 in the second standard cell SHC2, when measured in the first direction D1.

Due to the difference between the width of the top surface of the sixth active pattern AP6 of the third standard cell SHC3 and the sixth width W6, a width W6n of the sixth channel pattern CH6 in the second wide cell NFC2 may be larger than a width of the sixth channel pattern CH6 in the third standard cell SHC3, when measured in the first direction D1.

In sum, when measured in the first direction D1, the width of the channel pattern in each of the first and second wide cells NFC1 and NFC2 may be larger than the width of the channel pattern of the standard cell SHC. Thus, an overlap area between a gate electrode GE and the channel pattern may be increased, as will be described below. As a result, the electrical characteristics of the semiconductor device may be improved.

A source/drain pattern SD may be provided on each of the first region NR and the second region PR. In detail, the source/drain patterns SD may be respectively provided between the first channel patterns CH1, between the second channel patterns CH2, between the third channel patterns CH3, between the third channel patterns CH3, between the fifth channel patterns, and between the sixth channel patterns CH6.

The source/drain pattern SD on the first region NR may be impurity regions having a first conductivity type (e.g., n-type). In an embodiment, the source/drain pattern SD on the first region NR may contain the same semiconductor material (e.g., Si) as the substrate 100. The source/drain pattern SD on the second region PR may be impurity regions having a second conductivity type (e.g., p-type). In an embodiment, the source/drain pattern SD on the second region PR may contain a semiconductor material (e.g., SiGe) whose lattice constant is larger than that in each of the first to third semiconductor patterns SP1, SP2, and SP3.

A gate electrode GE may be disposed to cross at least one of the first to sixth channel patterns CH1 to CH6. In an embodiment, a plurality of gate electrodes GE may be provided. The gate electrodes GE may be extended lengthwise in the first direction D1 and may be spaced apart from each other in the second direction D2.

The gate electrode GE may include inner electrodes PO1 and an outer electrode PO2. The inner electrode PO1 of the gate electrode GE may be provided between the uppermost one of the semiconductor patterns SP1, SP2, and SP3 and an active pattern AP. The outer electrode PO2 of the gate electrode GE may be provided on the uppermost semiconductor pattern. In an embodiment, the inner electrode PO1 of the gate electrode GE may include three electrode portions, but the inventive concept is not limited to this example.

The gate electrode GE may include a first metal pattern and a second metal pattern on the first metal pattern. The first metal pattern may include a work-function metal, which can be used to adjust a threshold voltage of a transistor. In an embodiment, the first metal pattern may be formed of or include at least one of metallic materials (e.g., Ti, Mo, W, Cu, Al, Ta, Ru, Ir, and Co) and metal nitride materials (e.g., nitrides of Ti, Mo, W, Cu, Al, Ta, Ru, Ir, and Co). In an embodiment, the first metal pattern may further include carbon (C). The first metal pattern may be formed of or include at least one of metallic materials having different work functions.

In an embodiment, the second metal pattern may be formed of or include at least one of metallic materials (e.g., Ti, Mo, W, Cu, Al, Ta, Ru, Ir, and Co) whose electric resistances are lower than that of the first metal pattern.

In an embodiment, the inner electrode PO1 of the gate electrode GE may include the first metal pattern. In an embodiment, the outer electrode PO2 of the gate electrode GE may include the first metal pattern and the second metal pattern.

A gate capping pattern GC may be provided on a top surface of the gate electrode GE. In an embodiment, the gate capping pattern GC may be formed of or include at least one of SiON, SiCN, SiOCN, or SiN.

Gate spacers GS may be provided on side surfaces of the outer electrode PO2 of the gate electrode GE and may be extended to respective side surfaces of the gate capping pattern GC. The gate spacer GS may include a single layer or a composite layer. In an embodiment, the gate spacer GS may be formed of or include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover top, bottom, and opposite side surfaces of each of the first to third semiconductor patterns SP1, SP2, and SP3. The gate insulating pattern GI may be interposed between the outer electrode PO2 and the gate spacer GS. In an embodiment, the gate insulating pattern GI may be formed of or include at least one of silicon oxide (SiO₂), silicon oxynitride (SiON), and high-k dielectric materials. In the present specification, the high-k dielectric material may be defined as a material having a dielectric constant higher than that of silicon oxide.

A first interlayer insulating layer ILD1 may be provided on the substrate 100. The first interlayer insulating layer ILD1 may cover the gate spacers GS and the source/drain pattern SD. A second interlayer insulating layer ILD2 may be provided on the first interlayer insulating layer ILD1 to cover the gate capping pattern GC. A third interlayer insulating layer ILD3 may be provided on the second interlayer insulating layer ILD2. A fourth interlayer insulating layer ILD4 may be provided on the third interlayer insulating layer ILD3. In an embodiment, the first to fourth interlayer insulating layers ILD1, ILD2, ILD3, and ILD4 may be formed of or include silicon oxide (SiO₂).

Each of active contacts CA may be provided to penetrate the first and second interlayer insulating layers ILD1 and ILD2. A lower portion of each of the active contacts CA may be buried in an upper portion of the source/drain pattern SD. In an embodiment, the active contact CA may be formed of or include at least one of metallic materials (e.g., Ti, Mo, W, Cu, Al, Ta, Ru, Ir, and Co), metal nitride materials (e.g., containing Ti, Mo, W, Cu, Al, Ta, Ru, Ir, and Co), and metal silicide materials (e.g., containing Ti, Mo, W, Cu, Al, Ta, Ru, and Ir).

Gate contacts GT may be provided to penetrate the second interlayer insulating layer ILD2 and the gate capping pattern GC in the third direction D3. Each of the gate contacts GT may be buried in an upper portion of the outer electrode PO2 of the gate electrode GE. In an embodiment, the gate contacts GT may be formed of or include at least one of metallic materials (e.g., Ti, Mo, W, Cu, Al, Ta, Ru, Ir, and Co) and metal nitride materials (e.g., containing Ti, Mo, W, Cu, Al, Ta, Ru, Ir, and Co).

Cutting patterns CT may be interposed between the gate electrodes GE to separate them from each other. The cutting pattern CT may include a first cutting pattern CT1 that is interposed between first and second standard cells SHC1 and SHC2 and between the second and third standard cells SHC2 and SHC3. In addition, the cutting pattern CT may include a second cutting pattern CT2 interposed between the first and second wide cells NFC1 and NFC2.

The second cutting pattern CT2 may be shifted from the first cutting pattern CT1 in the first direction D1. When viewed in a plan view, the second cutting pattern CT2 may be interposed between the third active pattern AP3 of the first wide cell NFC1 and the fourth active pattern AP4 of the second wide cell NFC2. The second cutting pattern CT2 may be interposed between the third channel pattern CH3 on the third active pattern AP3 of the first wide cell NFC1 and the fourth channel pattern CH4 on the fourth active pattern AP4 of the second wide cell NFC2. In an embodiment, the first wide cell NFC1 may be defined between the first power line M1_R1 and the second cutting pattern CT2. In an embodiment, the second wide cell NFC2 may be defined between the second cutting pattern CT2 and the fourth power line M1_R4. The second cutting pattern CT2 may not be overlapped with each of the second power line M1_R2 and the third power line M1_R3.

The first to four power lines M1_R1, M1_R2, M1_R3, and M1_R4 and the first to twelfth lower interconnection lines M1_I1 to M1_I12 may be provided in the third interlayer insulating layer ILD3. The first to four power lines M1_R1, M1_R2, M1_R3, and M1_R4 and the first to twelfth lower interconnection lines M1_I1 to M1_I12 may be placed in the same or similar manner as described with reference to FIGS. 1 to 4.

First vias VI1 may be respectively provided between the interconnection lines (e.g., the first to four power lines M1_R1, M1_R2, M1_R3, and M1_R4 and the first to twelfth lower interconnection lines M1_I1 to M1_I12) and the contact plug patterns (e.g., the gate contact GT and the active contact CA).

The first to four power lines M1_R1, M1_R2, M1_R3, and M1_R4, the first to twelfth lower interconnection lines M1_I1 to M1_I12, and the first vias VI1 may constitute the first metal layer M1.

A second metal layer M2 may be provided on the first metal layer M1. The second metal layer M2 may include upper interconnection lines M2_I and second vias VI2, which connect the upper interconnection lines M2_I to the first metal layer M1.

Although only the first and second metal layers M1 and M2 are illustrated, the inventive concept is not limited to this example. A plurality of metal layers may be provided on the second metal layer M2.

FIG. 7 illustrates an example of possible layouts of the first wide cell NFC1. In an embodiment, the source/drain pattern SD on the first region NR of the first wide cell NFC1 may include a first pattern T1, a second pattern T2, and a third pattern T3, which are arranged in the second direction D2 and are spaced apart from each other. Similarly, the source/drain pattern SD on the second region PR of the first wide cell NFC1 may include a first pattern T1, a second pattern T2, and a third pattern T3, which are arranged in the second direction D2 and are spaced apart from each other.

The first pattern T1 on the first region NR of the first wide cell NFC1 may be connected to the first power line M1_R1 through the active contact CA and the first via VI1. Thus, the source voltage VSS may be applied to the first pattern T1 on the first region NR of the first wide cell NFC1. In an embodiment, the active contact CA may not be provided on the second pattern T2 on the first region NR of the first wide cell NFC1. If the transistor is turned on, a power may be delivered from the first pattern T1 on the first region NR of the first wide cell NFC1 to the second pattern T2 on the first region NR of the first wide cell NFC1.

The first pattern T1 on the second region PR of the first wide cell NFC1 may be connected to the second power line M1_R2 through the active contact CA and the first via VI1. Thus, the drain voltage VDD may be applied to the first pattern T1 on the second region PR of the first wide cell NFC1. The third pattern T3 on the second region PR of the first wide cell NFC1 may be connected to the second power line M1_R2 through the active contact CA and the first via VI1. Accordingly, the drain voltage VDD may be applied to the third pattern T3 on the second region PR of the first wide cell NFC1. In an embodiment, the active contact CA may be provided on the first pattern T1 on the second region PR of the first wide cell NFC1, but the first via VI1 may not be provided between the active contact CA and the second power line M1_R2. If the transistor is turned on, a power may be delivered from the first and third patterns T1 and T3 on the second region PR of the first wide cell NFC1 to the second pattern T2 on the second region PR of the first wide cell NFC1.

The second pattern T2 on the second region PR of the first wide cell NFC1 may be connected to the upper interconnection line M2_I through the active contact CA, the first via VI1, the fifth lower interconnection line M1_I5, and the second via VI2. The upper interconnection line M2_I may be connected to the first lower interconnection line M1_I1 through the second via VI2. The first lower interconnection line M1_I1 may be connected to the third pattern T3 on the first region NR of the first wide cell NFC1 through the first via VI1 and the active contact CA.

The gate electrodes GE may be connected to the fourth lower interconnection line M1_I4 through the gate contacts GT and the first vias VI1.

The layout of the first wide cell NFC1 described with reference to FIG. 7 is merely one example, and the inventive concept is not limited thereto, but may be modified in various ways by those skilled in the art.

FIG. 8 illustrates an example of possible layouts of the second wide cell NFC2. In an embodiment, the source/drain pattern SD on the first region NR of the second wide cell NFC2 may include the first pattern T1, the second pattern T2, and the third pattern T3, which are sequentially spaced apart from each other in the second direction D2. Similarly, the source/drain pattern SD on the second region PR of the second wide cell NFC2 may include the first pattern T1, the second pattern T2, and the third pattern T3, which are sequentially spaced apart from each other in the second direction D2.

The first pattern T1 on the first region NR of the second wide cell NFC2 may be connected to the third power line M1_R3 through the active contact CA and the first via VI1. Thus, the source voltage VSS may be applied to the first pattern T1 on the first region NR of the second wide cell NFC2. In an embodiment, the active contact CA may not be provided on the second pattern T2 on the first region NR of the second wide cell NFC2.

The second pattern T2 on the second region PR of the second wide cell NFC2 may be connected to the fourth power line M1_R4 through the active contact CA and the first via VI1. Thus, the drain voltage VDD may be applied to the second pattern T2 on the second region PR of the second wide cell NFC2. The active contact CA on the first pattern T1 on the second region PR of the second wide cell NFC2 may be connected to the active contact CA on the third pattern T3 on the second region PR of the second wide cell NFC2 through the first vias VI1 and twelfth lower interconnection line M1_I12. The active contact CA, which is provided on the third pattern T3 on the second region PR of the second wide cell NFC2, may be extended lengthwise in the first direction D1 and may be connected to the third pattern T3, which is provided on the first region NR of the second wide cell NFC2.

The layout of the second wide cell NFC2 described with reference to FIG. 8 is merely one example, and the inventive concept is not limited thereto, but may be modified in various ways by those skilled in the art.

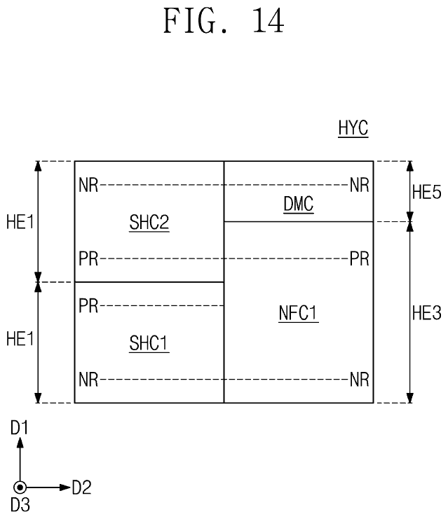

Hereinafter, semiconductor devices according to some example embodiments of the inventive concept will be described with reference to FIGS. 14 to 22. In the following description, a previously-described element may be identified by the same reference number without repeating an overlapping description thereof, for concise description.

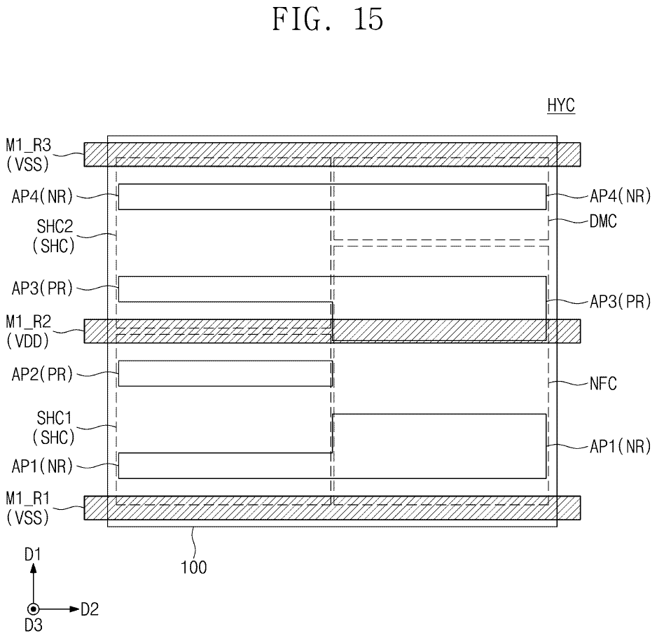

FIG. 14 is a block diagram illustrating a group cell of a semiconductor device according to an example embodiment of the inventive concept. FIG. 15 is a plan view illustrating a group cell of a semiconductor device according to an example embodiment of the inventive concept.

Referring to FIGS. 14 and 15, the group cell HYC may include two standard cells SHC1 and SHC2, one first wide cell NFC1, and one dummy cell DMC, unlike that described with reference to FIGS. 5 and 6.

In detail, first and second standard cells SHC1 and SHC2 may be sequentially disposed in the first direction D1. The first wide cell NFC1 may be adjacent to the first standard cell SHC1 in the second direction D2. The dummy cell DMC may be adjacent to the second standard cell SHC2 in the second direction D2. The first wide cell NFC1 and the dummy cell DMC may be sequentially arranged in the first direction D1. The first region NR of the second standard cell SHC2 and the first region NR of the dummy cell DMC may be connected to each other. If the first region NR is provided in the dummy cell DMC, the second region PR may not be provided in the dummy cell DMC. The fourth active pattern AP4 may be extended from the first region NR of the second standard cell SHC2 to the dummy cell DMC. When measured in the first direction D1, a width of the fourth active pattern AP4 in the second standard cell SHC2 may be substantially equal to a width of the fourth active pattern AP4 in the dummy cell DMC.

In an embodiment, the cell height of the group cell HYC may be about two times the first height HE1. Since the third height HE3 is smaller than the cell height of the group cell HYC, it may be possible to reserve an area for the dummy cell DMC. The cell height of the dummy cell DMC may be a fifth height HE5. In an embodiment, the first height HE1 may be about two times the fifth height HE5. Since the dummy cell DMC is provided in the group cell HYC, various interconnection lines may be provided in the dummy cell DMC, not in the first and second standard cells SHC1 and SHC2 and the first wide cell NFC1. This may make it possible to increase a degree of freedom in designing the layout of the semiconductor device.

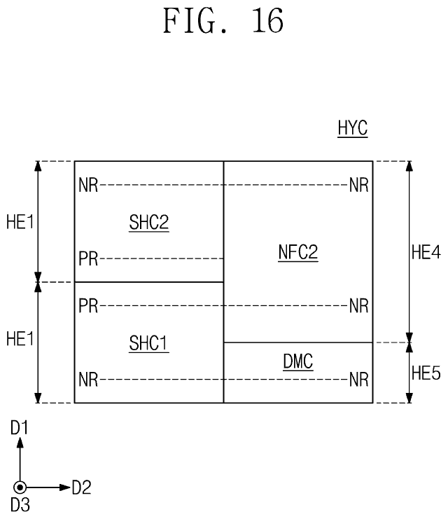

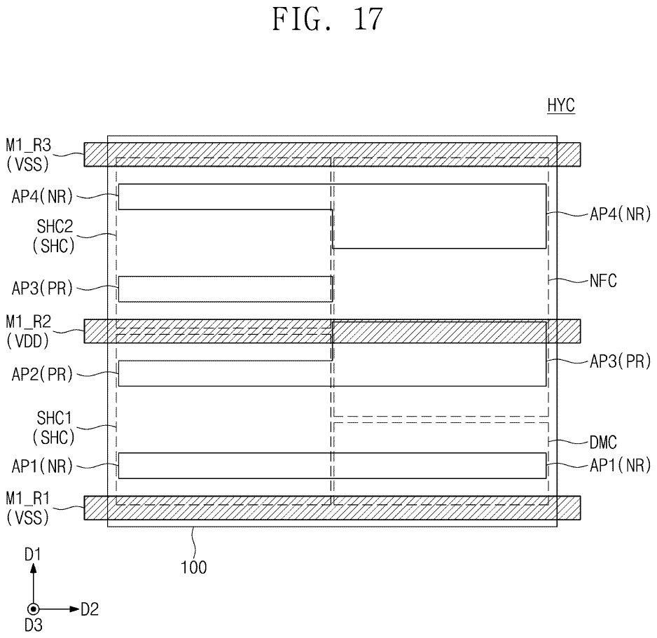

FIG. 16 is a block diagram illustrating a group cell of a semiconductor device according to an example embodiment of the inventive concept. FIG. 17 is a plan view illustrating a group cell of a semiconductor device according to an example embodiment of the inventive concept.

Referring to FIGS. 16 and 17, unlike that described with reference to FIGS. 5 and 6, the group cell HYC may include two standard cells SHC1 and SHC2, one second wide cell NFC2, and one dummy cell DMC.

Unlike the embodiment of FIGS. 14 and 15, the second wide cell NFC2 may be adjacent to the second standard cell SHC2 in the second direction D2. The dummy cell DMC may be adjacent to the first standard cell SHC1 in the second direction D2. The first region NR of the first standard cell SHC1 and the first region NR of the dummy cell DMC may be connected to each other. The first active pattern AP1 may be extended from the first region NR of the first standard cell SHC1 to the dummy cell DMC. When measured in the first direction D1, a width of the first active pattern AP1 in the first standard cell SHC1 may be substantially equal to a width of the first active pattern AP1 in the dummy cell DMC.

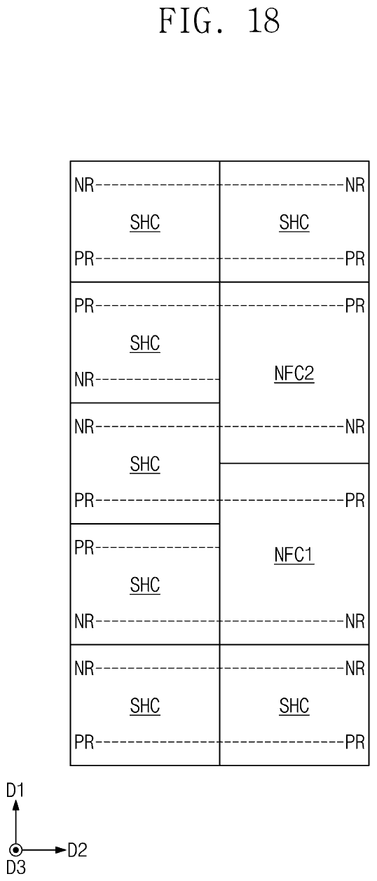

FIGS. 18 to 20 are block diagrams illustrating a group cell of a semiconductor device according to example embodiments of the inventive concept.

Referring to FIGS. 18 to 20, the logic cells may be placed in various ways. For example, in the embodiment of FIG. 18, two standard cells SHC may be provided adjacent to the group cell HYC of FIG. 5 in the first direction D1. Two standard cells SHC may be provided adjacent to the group cell HYC of FIG. 5 in the opposite direction of the first direction D1.

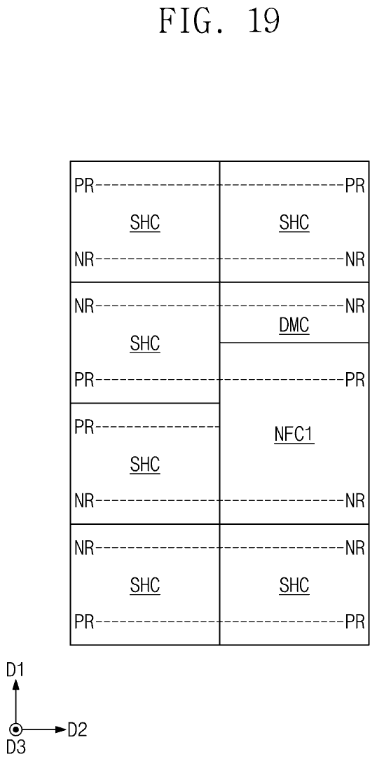

In the embodiment of FIG. 19, two standard cells SHC may be provided adjacent to the group cell HYC of FIG. 14 in the first direction D1. Two standard cells SHC may be provided adjacent to the group cell HYC of FIG. 14 in the opposite direction of the first direction D1.

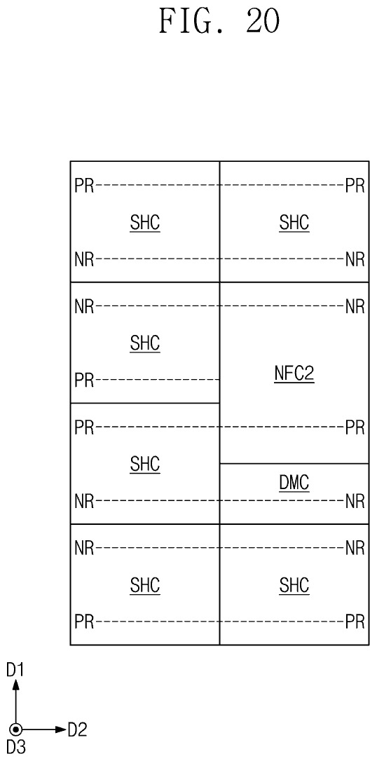

In the embodiment of FIG. 20, two standard cells SHC may be provided adjacent to the group cell HYC of FIG. 16 in the first direction D1. Two standard cells SHC may be provided adjacent to the group cell HYC of FIG. 16 in the opposite direction of the first direction D1.

The placement of the logic cells is not limited to the examples described with reference to FIGS. 18 to 20, but may be modified in various ways by those skilled in the art.

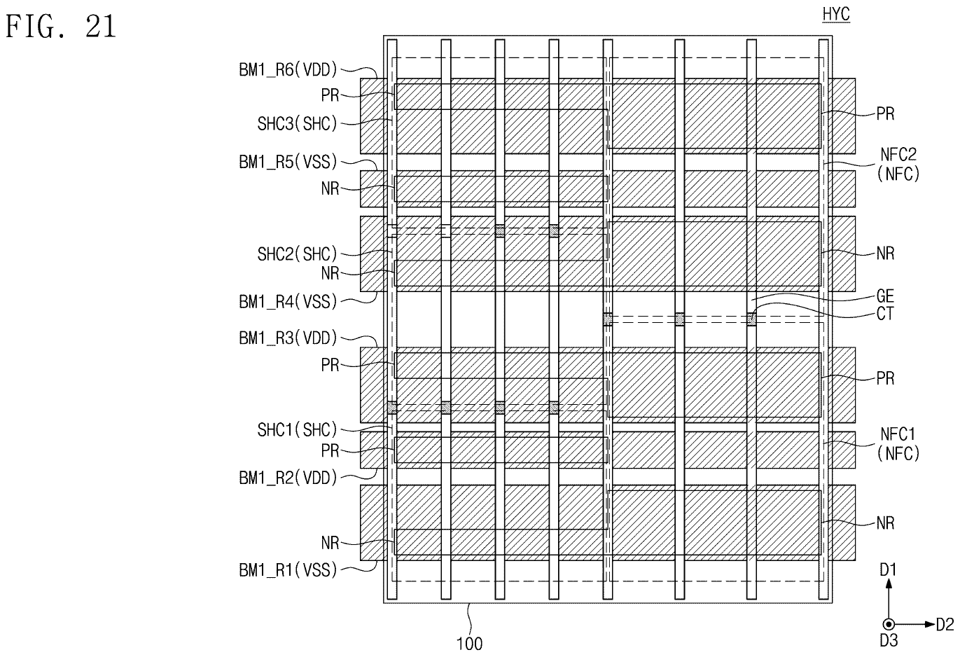

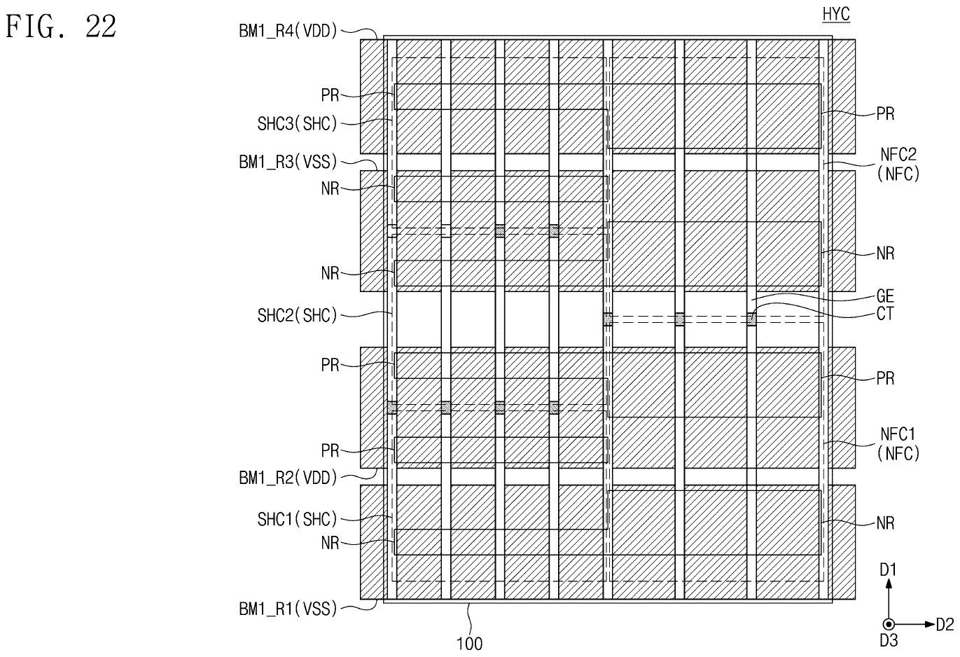

FIGS. 21 and 22 are plan views illustrating a group cell of a semiconductor device according to example embodiments of the inventive concept.

Referring to FIGS. 21 and 22, the first to four power lines M1_R1, M1_R2, M1_R3, and M1_R4 may not be provided, unlike the previous embodiment. However, power lines, which are used to deliver the source voltage VSS or the drain voltage VDD, may be buried in the substrate 100, and in this case, the power may be supplied to the transistor of the logic cell via a back-side interconnection structure. Here, the substrate 100 may be an insulating substrate that is formed of or includes an insulating material.

Referring to FIG. 21, first to sixth back-side power lines BM1_R1 to BM1_R6 may be buried in the substrate 100.

The first back-side power line BM1_R1 may be provided below the first region NR of each of the first standard cell SHC1 and the first wide cell NFC1 and may be extended in the second direction D2. The second back-side power line BM1_R2 may be provided below the second region PR of the first standard cell SHC1 and may be extended in the second direction D2. The third back-side power line BM1_R3 may be provided below the second region PR of each of the second standard cell SHC2 and the first wide cell NFC1 and may be extended in the second direction D2. The fourth back-side power line BM1_R4 may be provided below the first region NR of each of the second standard cell SHC2 and the second wide cell NFC2 and may be extended in the second direction D2. The fifth back-side power line BM1_R5 may be provided below the first region NR of the third standard cell SHC3 and may be extended in the second direction D2. The sixth back-side power line BM1_R6 may be provided below the second region PR of each of the third standard cell SHC3 and the second wide cell NFC2 and may be extended in the second direction D2.

Each of the first, fourth, and fifth back-side power lines BM1_R1, BM1_R4, and BM1_R5 may be used as a conduction path of delivering the source voltage VSS. Each of the second, third, and six back-side power lines BM1_R2, BM1_R3, and BM1_R6 may be used as a conduction path of delivering the drain voltage VDD.

The first back-side power line BM1_R1 may be connected to the source/drain pattern SD, which is placed on the first region NR of each of the first standard cell SHC1 and the first wide cell NFC1, through an additional contact. The second back-side power line BM1_R2 may be connected to the source/drain pattern SD on the second region PR of the first standard cell SHC1 through an additional contact. The third back-side power line BM1_R3 may be connected to the source/drain pattern SD on the second region PR of each of the second standard cell SHC2 and the first wide cell NFC1 through an additional contact. The fourth back-side power line BM1_R4 may be connected to the source/drain pattern SD on the first region NR of each of the second standard cell SHC2 and the second wide cell NFC2 through an additional contact. The fifth back-side power line BM1_R5 may be connected to the source/drain pattern SD on the first region NR of the third standard cell SHC3 through an additional contact. The sixth back-side power line BM1_R6 may be connected to the source/drain pattern SD on the second region PR of each of the third standard cell SHC3 and the second wide cell NFC2 through an additional contact.

Referring to FIG. 22, the first to four back-side power lines BM1_R1 to BM1_R4 may be buried in the substrate 100.

The first back-side power line BM1_R1 may be provided below the first region NR of each of the first standard cell SHC1 and the first wide cell NFC1 and may be extended lengthwise in the second direction D2. The second back-side power line BM1_R2 may be provided below the second region PR of the first standard cell SHC1 and below the second region PR of each of the second standard cell SHC2 and the first wide cell NFC1 and may be extended lengthwise in the second direction D2. The third back-side power line BM1_R3 may be provided below the first region NR of each of the second standard cell SHC2 and the second wide cell NFC2 and below the first region NR of the third standard cell SHC3 and may be extended lengthwise in the second direction D2. The fourth back-side power line BM1_R4 may be provided below the second region PR of each of the third standard cell SHC3 and the second wide cell NFC2 and may be extended lengthwise in the second direction D2. Each of the first and third back-side power lines BM1_R1 and BM1_R3 may be used as a conduction path of delivering the source voltage VSS. Each of the second and fourth back-side power lines BM1_R2 and BM1_R4 may be used as a conduction path of delivering the drain voltage VDD.

The second back-side power line BM1_R2 may be connected to the source/drain pattern SD on the second region PR of the first standard cell SHC1 and the source/drain pattern SD on the second region PR of each of the second standard cell SHC2 and the first wide cell NFC1 through an additional contact. The third back-side power line BM1_R3 may be connected to the source/drain pattern SD on the first region NR of each of the second standard cell SHC2 and the second wide cell NFC2 and the source/drain pattern SD on the first region NR of the third standard cell SHC3 through an additional contact.

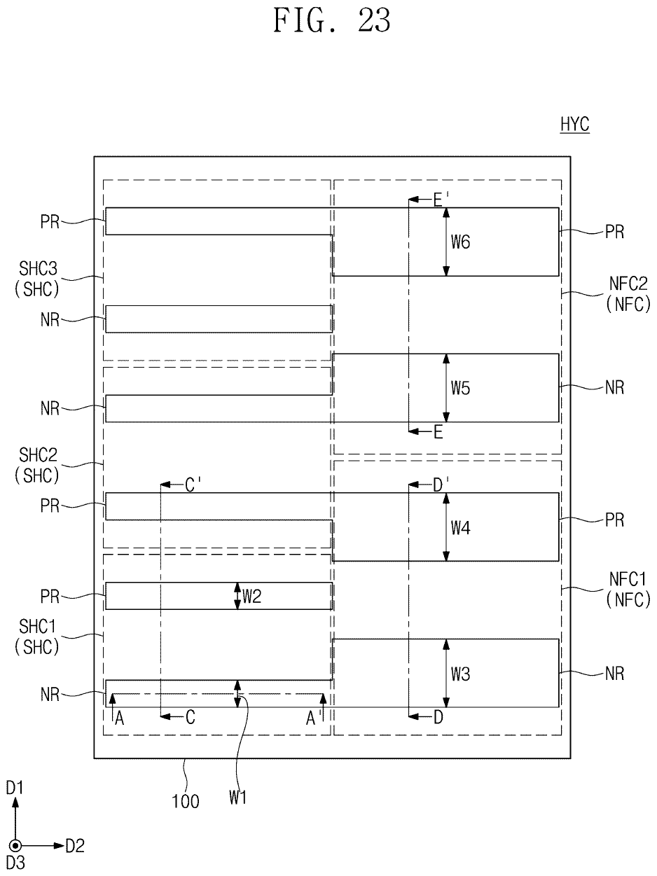

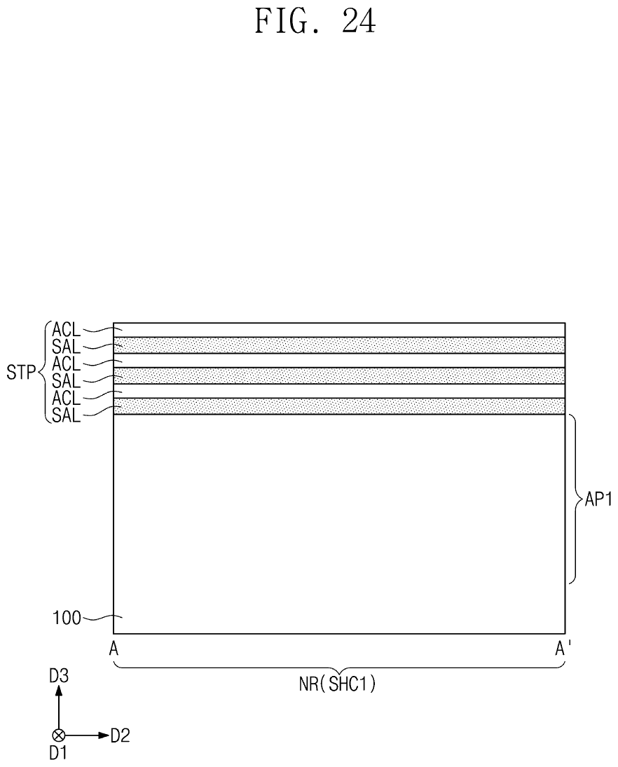

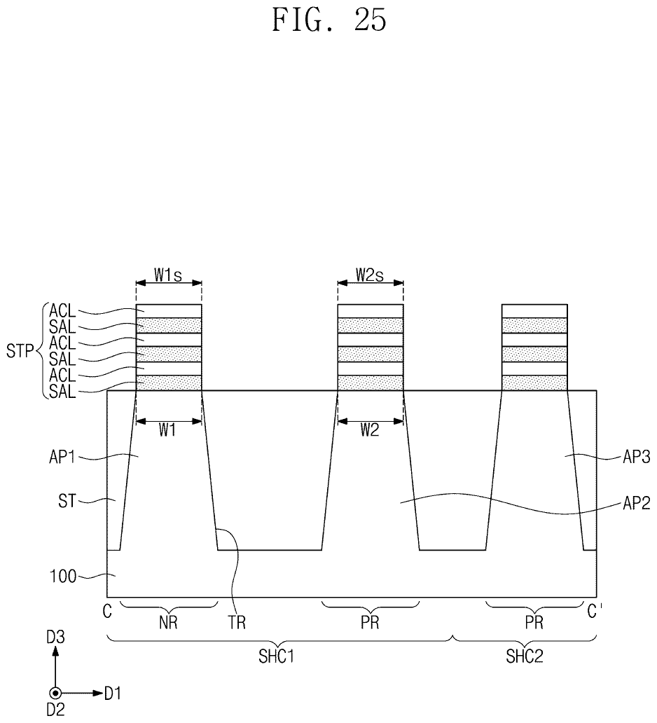

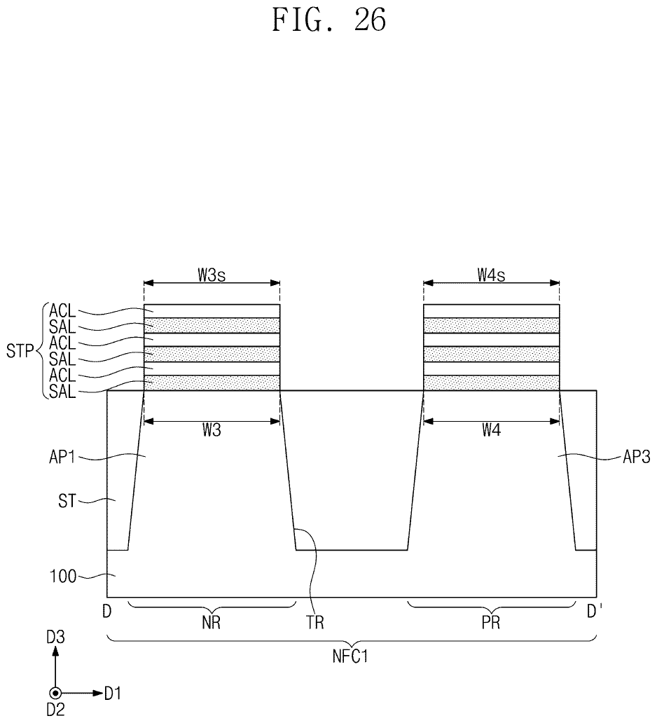

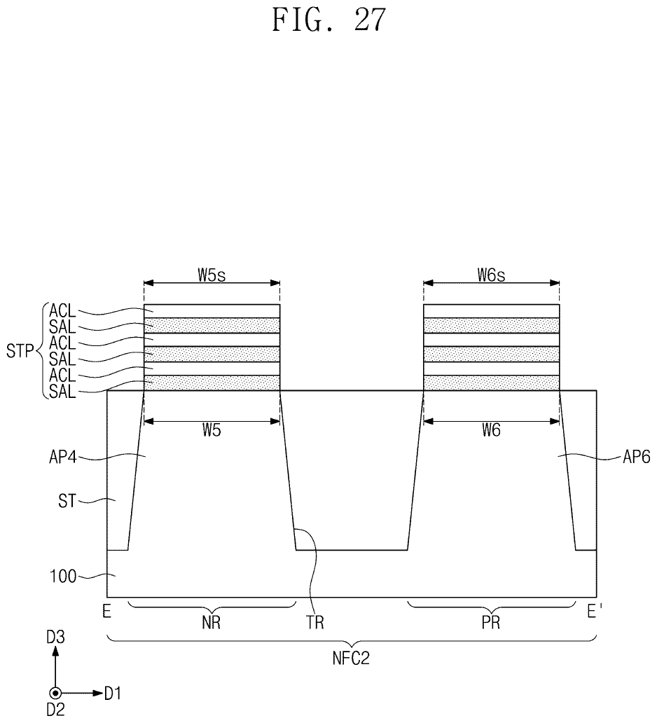

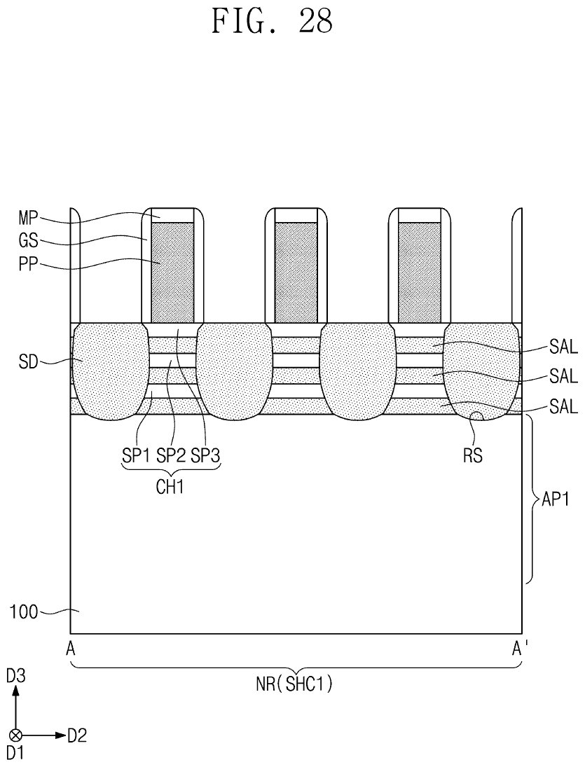

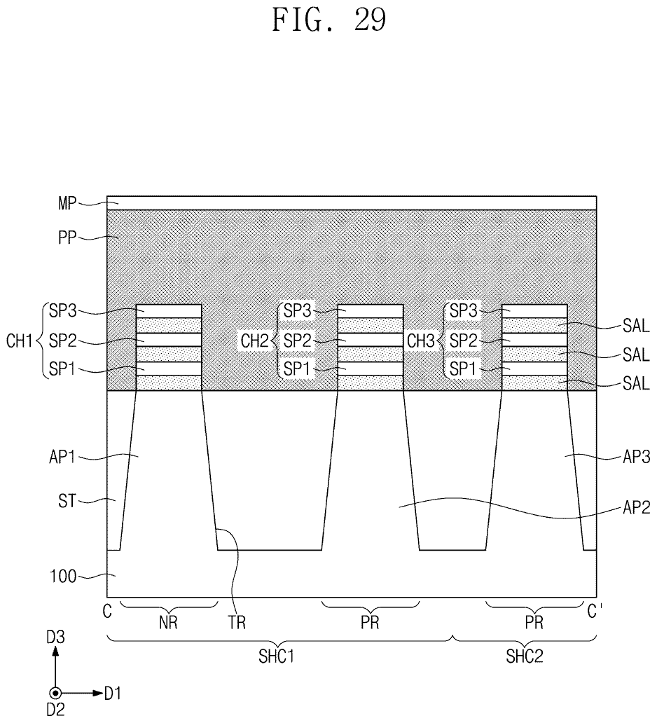

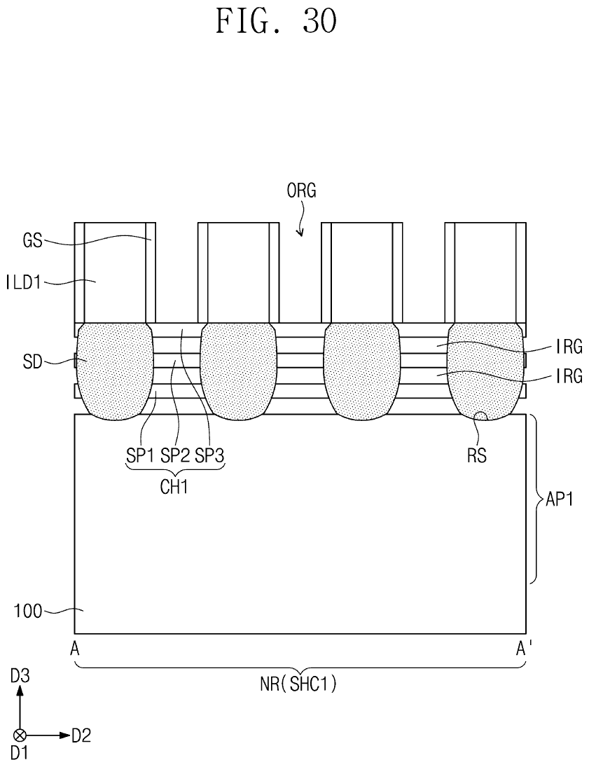

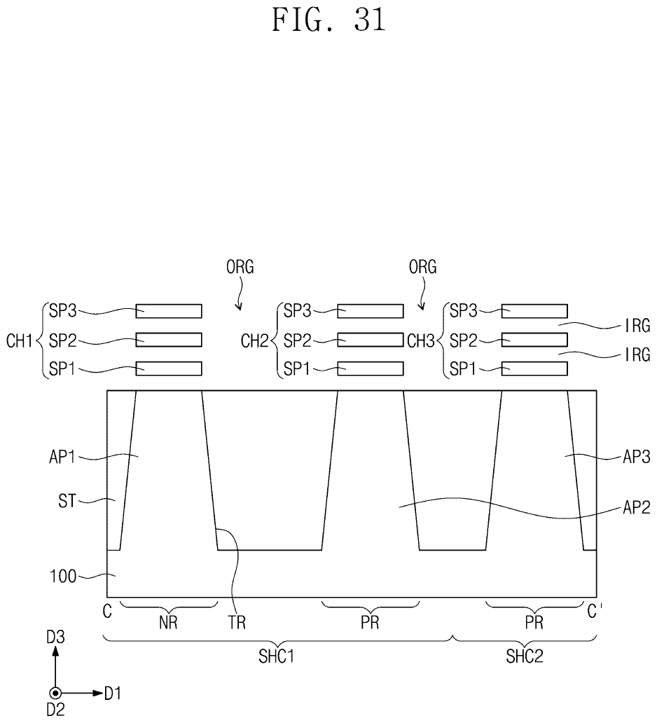

FIGS. 23 to 31 are diagrams illustrating a method of fabricating a semiconductor device, according to an example embodiment of the inventive concept. In detail, FIG. 23 is a plan view illustrating a semiconductor device according to an example embodiment of the inventive concept. FIG. 24 is a sectional view corresponding to a line A-A′ of FIG. 23. FIG. 25 is a sectional view corresponding to a line C-C′ of FIG. 23. FIG. 26 is a sectional view corresponding to a line D-D′ of FIG. 23. FIG. 27 is a sectional view corresponding to a line E-E′ of FIG. 23. FIGS. 28 and 30 are sectional views corresponding to the line A-A′ of FIG. 6. FIGS. 29 and 31 are sectional views corresponding to the line C-C′ of FIG. 6.

Referring to FIGS. 23 to 27, the substrate 100 including the first and second regions NR and PR may be provided. Stacking patterns STP may be formed on the first and second regions NR and PR. In an embodiment, the formation of the stacking patterns STP may include alternately stacking semiconductor layers ACL and first sacrificial layers SAL on the substrate 100, forming mask patterns (not shown) extended in the second direction D2, and performing a patterning process using the mask patterns as an etch mask. A portion of the substrate 100 may be removed during the patterning process to form the trenches TR. The device isolation patterns ST may be formed to fill the trenches TR.

As a result of the patterning process, the first to sixth active patterns AP1 to AP6 may be formed on the substrate 100. As a result of the patterning process, the first to sixth active patterns AP1 to AP6 may have first to sixth widths W1 to W6, respectively.

The first sacrificial layers SAL may be formed of or include a material having an etch selectivity with respect to the semiconductor layers ACL. Thus, it may be possible to prevent the semiconductor layers ACL from being removed or excessively etched in a subsequent process of removing the first sacrificial layers SAL. In an embodiment, the semiconductor layers ACL may be formed of or include one of silicon (Si), germanium (Ge), and silicon-germanium (SiGe), and the first sacrificial layers SAL may be formed of or include a material that is chosen from the group consisting of silicon (Si), germanium (Ge), and silicon-germanium (SiGe) and is different from that in the semiconductor layers ACL.

Referring to FIGS. 6, 28, and 29, sacrificial patterns PP may be formed on the substrate 100 to extend in the first direction D1. The sacrificial patterns PP may be formed to cover top surfaces of the device isolation patterns ST and side and top surfaces of the stacking patterns STP of FIG. 24. In an embodiment, the formation of the sacrificial patterns PP may include forming a sacrificial layer (not shown) on the substrate 100, forming hard mask patterns MP on the sacrificial layer, and forming the sacrificial patterns PP by removing a portion of the sacrificial layer using the hard mask patterns MP as an etch mask. In an embodiment, the sacrificial pattern PP may be formed of or include polysilicon. Next, the gate spacers GS may be formed on side surfaces of the sacrificial patterns PP.

Recesses RS may be formed by removing a portion of the stacking pattern STP of FIG. 24 using the hard mask patterns MP, the gate spacers GS, and the sacrificial patterns PP as a mask. Due to the recesses RS, the semiconductor layers ACL of FIG. 24 may be divided into the first channel patterns CH1, the second channel patterns CH2, the third channel patterns CH3, the fourth channel patterns CH4 of FIG. 13, the fifth channel patterns, and the sixth channel patterns CH6 of FIG. 13. Thereafter, the source/drain patterns SD may be formed to fill the recesses RS.

Referring to FIGS. 6, 30, and 31, the first interlayer insulating layer ILD1 may be formed to cover the source/drain patterns SD. Next, the sacrificial patterns PP and the hard mask patterns MP may be removed. Thus, an outer region ORG may be defined between the gate spacers GS.

The sacrificial layers SAL of FIG. 28 exposed by the outer region ORG may be selectively removed. Here, the first to third semiconductor patterns SP1, SP2, and SP3 may be hardly or less removed, due to the high etch selectivity of the sacrificial layers SAL of FIG. 28.

Inner regions IRG may be formed in empty regions, which are formed by removing the sacrificial layers SAL of FIG. 28. In detail, the inner regions IRG may be formed between the first to third semiconductor patterns SP1, SP2, and SP3.

Referring back to FIGS. 6 and 9 to 13, the gate insulating pattern GI may be formed in each of the inner regions IRG of FIG. 30 and the outer region ORG of FIG. 30. The gate insulating pattern GI may be formed to enclose each of the first to third semiconductor patterns SP1, SP2, and SP3. For example, the gate insulating pattern GI may surround each of the first to third semiconductor patterns SP1, SP2, and SP3.

The gate electrode GE may be formed on the gate insulating pattern GI. The gate electrode GE may include the inner electrode PO1, which is formed in each of the inner regions IRG of FIG. 30, and the outer electrode PO2, which is formed in the outer region ORG of FIG. 30. Next, the gate capping pattern GC may be formed on the outer electrode PO2 of the gate electrode GE.

The second interlayer insulating layer ILD2 may be formed on the first interlayer insulating layer ILD1 and the gate capping pattern GC.

The active contacts CA may be formed to penetrate the first interlayer insulating layer ILD1 and the second interlayer insulating layer ILD2 and may be connected to the source/drain patterns SD. For example, the active contacts CA may contact the source/drain patterns SD.

The gate contacts GT may be formed to penetrate the second interlayer insulating layer ILD2 and the gate capping pattern GC and may be connected to the gate electrodes GE. For example, the gate contacts GT may contact the gate electrodes GE.

The third interlayer insulating layer ILD3 and the fourth interlayer insulating layer ILD4 may be formed on the second interlayer insulating layer ILD2. For example, the fourth interlayer insulating layer ILD4 may be disposed on and may contact the third interlayer insulating layer ILD3, and the third interlayer insulating layer ILD3 may be disposed on and may contact the second interlayer insulating layer ILD2. The first metal layer M1 may be formed in the third interlayer insulating layer ILD3, and the second metal layer M2 may be formed in the fourth interlayer insulating layer ILD4.

According to an embodiment of the inventive concept, a wide cell may be provided to have a cell height that is 1.25 to 1.75 times greater than a cell height of a standard cell. For example, a cell height of the wide cell may be 1.25 to 1.75 times a pitch between the first power line and the second power line. In addition, the wide cell and one standard cell may share an NMOSFET region, and the wide cell and another standard cell may share a PMOSFET region. A width of a channel pattern of the wide cell may be larger than a width of a channel pattern of the standard cell. The semiconductor device may include the standard cells as well as the wide cells described above, and in this case, the electrical characteristics of the semiconductor device may be improved.

Three standard cells and two wide cells, which are configured to have the afore-described features, may constitute one group cell. By placing the standard cells and the wide cells at the ratio of 3:2, there may be no need to insert a dummy cell in the group cell. Accordingly, it may be possible to reduce an area loss in the group cell and place more logic cells in the semiconductor device. As a result, the integration density of the semiconductor device may be increased.

Each group cell may be composed of two standard cells and one wide cell, which is configured to have the afore-described features. In the case where the standard cells and the wide cells are placed at the ratio of 2:1, one dummy cell may be inserted in an empty space within the group cell. In this case, some of interconnection lines of metal layers may be placed in the dummy cell, not in the standard cell or the wide cell. This may make it possible to increase a degree of freedom in designing the layout of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a first power line and a second power line disposed on a substrate and spaced apart from each other in a first direction parallel to a top surface of the substrate;
a first standard cell defined between the first power line and the second power line; and
a first wide cell adjacent to the first standard cell,
wherein a cell height of the first wide cell is 1.25 to 1.75 times a pitch between the first power line and the second power line,
wherein each of the first standard cell and the first wide cell comprises a first active pattern,
wherein the first active pattern of the first standard cell is connected to the first active pattern of the first wide cell, and
wherein a width of a top surface of the first active pattern of the first wide cell is larger than a width of a top surface of the first active pattern of the first standard cell, when measured in the first direction.

2. The semiconductor device of claim 1,
wherein the first standard cell comprises a second active pattern, and
wherein the second active pattern is not extended into the first wide cell.

3. The semiconductor device of claim 1,
wherein the first standard cell comprises a second active pattern, and
wherein the width of the top surface of the first active pattern of the first standard cell is substantially equal to a width of a top surface of the second active pattern of the first standard cell, when measured in a second direction crossing the first direction.

4. The semiconductor device of claim 1, further comprising:
a second standard cell adjacent to the first standard cell in the first direction,
wherein each of the second standard cell and the first wide cell comprises a third active pattern, and
wherein the third active pattern of the second standard cell is connected to the third active pattern of the first wide cell.

5. The semiconductor device of claim 4, wherein a width of a top surface of the third active pattern of the first wide cell is larger than a width of a top surface of the third active pattern of the second standard cell, when measured in the first direction.

6. The semiconductor device of claim 4, further comprising:
a third power line spaced apart from the first power line in the first direction, with the second power line interposed therebetween,
wherein the second standard cell is defined between the second power line and the third power line,
wherein the first active pattern of the first wide cell is interposed between the first power line and the second power line, when viewed in a plan view, and
wherein at least a portion of the third active pattern of the first wide cell is interposed between the second power line and the third power line, when viewed in the plan view.

7. The semiconductor device of claim 4,
wherein a side surface of the first active pattern of the first wide cell protrudes in the first direction, when compared to a side surface of the first active pattern of the first standard cell, and
wherein a side surface of the third active pattern of the first wide cell protrudes in an opposite direction of the first direction, when compared to a side surface of the third active pattern of the second standard cell.

8. A semiconductor device, comprising:
a first power line and a second power line disposed on a substrate and spaced apart from each other in a first direction parallel to a top surface of the substrate;
a first standard cell defined between the first power line and the second power line;
a second standard cell adjacent to the first standard cell in the first direction;
a first wide cell adjacent to the first standard cell;
a first active pattern extended from the first standard cell to the first wide cell;
a second active pattern extended in the first standard cell;
a third active pattern extended from the second standard cell to the first wide cell; and
a fourth active pattern extended in the second standard cell,
wherein the first wide cell is spaced apart from the fourth active pattern in the first direction,
wherein a width of a top surface of the first active pattern in the first wide cell is larger than a width of a top surface of the first active pattern in the first standard cell, when measured in the first direction, and
wherein a width of a top surface of the third active pattern in the first wide cell is larger than a width of a top surface of the third active pattern in the second standard cell.

9. The semiconductor device of claim 8, wherein the second active pattern is not extended into the first wide cell.

10. The semiconductor device of claim 8, further comprising:
a first cutting pattern between the second active pattern in the first standard cell and the third active pattern in the second standard cell; and
a second cutting pattern between the third active pattern in the first wide cell and the fourth active pattern.

11. The semiconductor device of claim 10, wherein the first wide cell is defined between the first power line and the second cutting pattern, when viewed in a plan view.

12. The semiconductor device of claim 8,
wherein a side surface of the first active pattern in the first wide cell protrudes in the first direction, when compared to a side surface of the first active pattern in the first standard cell, and
wherein a side surface of the third active pattern in the first wide cell protrudes in an opposite direction of the first direction, when compared to a side surface of the third active pattern in the second standard cell.

13. The semiconductor device of claim 8, further comprising:
a second wide cell adjacent to the first wide cell in the first direction,
wherein the fourth active pattern is extended from the second standard cell to the second wide cell, and
wherein a side surface of the fourth active pattern in the second wide cell protrudes in the first direction, when compared to a side surface of the fourth active pattern in the second standard cell.

14. The semiconductor device of claim 8, further comprising:
a dummy cell adjacent to the first wide cell in the first direction,
wherein the fourth active pattern is extended from the second standard cell to the dummy cell, and
wherein a width of a top surface of the fourth active pattern in the second standard cell is substantially equal to a width of a top surface of the fourth active pattern in the dummy cell, when measured in the first direction.

15. The semiconductor device of claim 8, wherein a cell height of the first wide cell is 1.25 to 1.75 times a pitch between the first power line and the second power line.

16. A semiconductor device, comprising:
a first power line and a second power line disposed on a substrate and spaced apart from each other in a first direction parallel to a top surface of the substrate;
a first standard cell defined between the first power line and the second power line;
a second standard cell adjacent to the first standard cell in the first direction;
a third standard cell spaced apart from the first standard cell in the first direction, with the second standard cell interposed therebetween;
a first wide cell adjacent to the first standard cell in a second direction crossing the first direction; and
a second wide cell adjacent to the third standard cell in the second direction and adjacent to the first wide cell in the first direction,
wherein a cell height of each of the first and second wide cells is 1.25 to 1.75 times a pitch between the first and second power lines.

17. The semiconductor device of claim 16, further comprising:
a third power line and a fourth power line, which are sequentially arranged in the first direction and are spaced apart from the second power line,
wherein the first to third standard cells and the first and second wide cells are interposed between the first and fourth power lines.

18. The semiconductor device of claim 17, wherein a sum of the cell height of the first wide cell and the cell height of the second wide cell is substantially equal to a pitch between the first and fourth power lines.

19. The semiconductor device of claim 16, further comprising:
a first active pattern extended from the first standard cell to the first wide cell;
a second active pattern extended in the first standard cell; and
a third active pattern extended from the second standard cell to the first wide cell,
wherein, when measured in the first direction, a width of a top surface of the first active pattern in the first wide cell is larger than a width of a top surface of the first active pattern in the first standard cell, and
wherein a width of a top surface of the third active pattern in the first wide cell is larger than a width of a top surface of the third active pattern in the second standard cell.

20. The semiconductor device of claim 16, further comprising:
a fourth active pattern extended from the second standard cell to the second wide cell;
a fifth active pattern extended in the third standard cell; and
a sixth active pattern extended from the third standard cell to the second wide cell,
wherein, when measured in the first direction, a width of a top surface of the fourth active pattern in the second wide cell is larger than a width of a top surface of the fourth active pattern in the second standard cell, and
wherein a width of a top surface of the sixth active pattern in the second wide cell is larger than a width of a top surface of the sixth active pattern in the third standard cell.
